(19) United States
(12) Patent Application Publication
(10) Pub. No.: US 2024/0109997 A1
(43) Pub. Date: Apr. 4, 2024

(54) RESIN, COMPOSITION, RESIST PATTERN FORMATION METHOD, CIRCUIT PATTERN FORMATION METHOD AND METHOD FOR PURIFYING RESIN

(71) Applicant: Mitsubishi Gas Chemical Company, Inc., Tokyo (JP)

(72) Inventors: Junya HORIUCHI, Hiratsuka-shi, Kanagawa (JP); Takashi MAKINOSHIMA, Hiratsuka-shi, Kanagawa (JP); Takashi SATO, Hiratsuka-shi, Kanagawa (JP); Masatoshi ECHIGO, Tokyo (JP)

(21) Appl. No.: 18/277,366

(22) PCT Filed: Jan. 28, 2022
(86) PCT No.: PCT/JP2022/003346

§ 371 Date: Aug. 15, 2023

(30) Foreign Application Priority Data
Feb. 16, 2021 (JP) 2021-022454

(51) Int. Cl. C08G 8/20; G03F 7/11; G03F 7/20; G03F 7/26; H01L 21/027

(52) U.S. Cl. CPC C08G 8/20; G03F 7/11; G03F 7/20; G03F 7/26; H01L 21/0274

(57) ABSTRACT

An object of the present invention is to provide a novel resin that is useful as a film forming material for lithography and the like. The problem can be solved by a resin containing a constituent unit represented by the following formula (1) or (1)′:

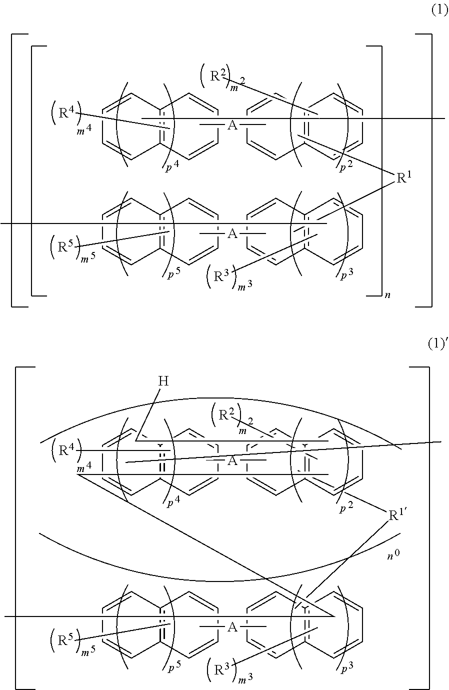

wherein the variables in the formulas are as described in the specification.

### TECHNICAL FIELD

The present invention relates to a resin, a composition, a resist pattern formation method, a circuit pattern formation method, and a method for purifying the resin.

### BACKGROUND ART

In the production of semiconductor devices, fine processing is practiced by lithography using photoresist materials. In recent years, further miniaturization based on pattern rules has been demanded along with increase in the integration and speed of LSI (large scale integrated circuits). The light source for lithography used upon forming resist patterns has been shifted to ArF excimer laser (193 nm) having a shorter wavelength from KrF excimer laser (248 nm). The introduction of extreme ultraviolet (EUV, 13.5 nm) is also expected (for example, see Non Patent Literature 1).

However, in lithography using a conventional resist material, roughness occurs on a pattern surface; the pattern dimension becomes difficult to be controlled; and there is a limitation in miniaturization. Accordingly, various attempts have been made to provide a resist pattern having a higher resolution.

Also, as the miniaturization of resist patterns proceeds, the problem of resolution or the problem of collapse of resist patterns after development arises. Therefore, resists have been desired to have a thinner film. However, if resists merely have a thinner film, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern (for example, see Non Patent Literatures 2 and 3).

Various resist underlayer films for such a process are currently known. For example, as a material for realizing resist underlayer films for lithography having the selectivity of a dry etching rate close to that of resists, unlike conventional resist underlayer films having a fast etching rate, an underlayer film forming material for a multilayer resist process containing a resin component having at least a substituent that generates a sulfonic acid residue by eliminating a terminal group under application of predetermined energy, and a solvent has been suggested (see Patent Literature 1). Further, in order to achieve a resist underlayer film for lithography having the selectivity of a dry etching rate smaller than that of resists, a resist underlayer film material comprising a polymer having a specific repeat unit has been suggested (see Patent Literature 2). Furthermore, as a material for realizing resist underlayer films for lithography having the selectivity of a dry etching rate smaller than that of semiconductor substrates, a resist underlayer film material comprising a polymer prepared by copolymerizing a repeat unit of an acenaphthylene and a repeat unit having a substituted or unsubstituted hydroxy group has been suggested (see Patent Literature 3).

Meanwhile, as materials having high etching resistance for this kind of resist underlayer film, amorphous carbon underlayer films formed by chemical vapour deposition (CVD) using methane gas, ethane gas, acetylene gas, or the like as a raw material are well known. However, resist underlayer film materials that can form resist underlayer films by a wet process such as spin coating or screen printing have been demanded from the viewpoint of a process.

The present inventors have also proposed an underlayer film forming composition for lithography containing a compound having a specific structure and an organic solvent (see Patent Literature 4) as a material that is excellent in etching resistance, has high heat resistance, and is soluble in a solvent and applicable to a wet process.

As for methods for forming an intermediate layer used in the formation of a resist underlayer film in a three-layer process, for example, a method for forming a silicon nitride film (see Patent Literature 5) and a CVD formation method for a silicon nitride film (see Patent Literature 6) are known. Also, as intermediate layer materials for a three-layer process, materials comprising a silsesquioxane-based silicon compound are known (see Patent Literatures 7 and 8).

### CITATION LIST

### Patent Literature

Patent Literature 1: Japanese Patent Laid-Open No. 2004-177668
Patent Literature 2: Japanese Patent Laid-Open No. 2004-271838
Patent Literature 3: Japanese Patent Laid-Open No. 2005-250434
Patent Literature 4: International Publication No. WO 2013/024779
Patent Literature 5: Japanese Patent Laid-Open No. 2002-334869
Patent Literature 6: International Publication No. WO 2004/066377
Patent Literature 7: Japanese Patent Laid-Open No. 2007-226170
Patent Literature 8: Japanese Patent Laid-Open No. 2007-226204

### Non Patent Literature

Non Patent Literature 1: Shinji Okazaki et al., and eight others “Development of Lithography Technology in These 40 Years”, S&T Publishing Inc., December 2016, pp. 1-21
Non Patent Literature 2: Shinji Okazaki et al., “New Trends of Photoresists”, CMC Publishing Co., Ltd., September 2009, pp. 273-275
Non Patent Literature 3: Research Division, Toray Research Center. Inc., “Microfabrication Technologies Supporting Next-Generation Semiconductors” Research Division, Toray Research Center, August 2006, pp. 178-180

### SUMMARY OF INVENTION

### Technical Problem

However, it has been required for film forming materials for lithography or optical component forming materials to have high levels of solubility in organic solvents, etching resistance and resist pattern formability at the same time.

Therefore, the present invention has an object to provide a novel resin that is particularly useful as a film forming material for lithography, and a composition, a resist pattern formation method, a circuit pattern formation method, and a method for purifying the resin.

### Solution to Problem

The present inventors have, as a result of devoted examinations to solve the problems described above, found out that a resin having a specific structure is particularly useful as a film forming material for lithography, leading to completion of the present invention.

More specifically, the present invention is as follows.

[1]

A resin comprising a constituent unit represented by the following formula (1) or (1)′:

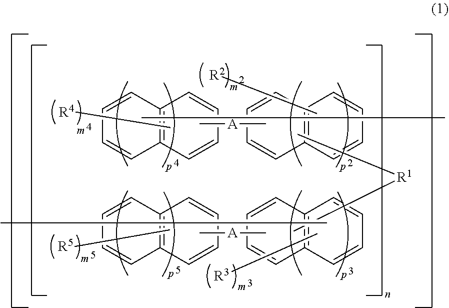

wherein
A is a single bond, an alkylene having 1 to 4 carbon atoms and optionally having a substituent, or a heteroatom;
R¹ is a 2n-valent group having 1 to 30 carbon atoms;
R² to R⁵ are each independently a linear alkyl group having 1 to 10 carbon atoms, a branched alkyl group having 3 to 10 carbon atoms, a cyclic alkyl group having 3 to 10 carbon atoms, an aryl group having 6 to 10 carbon atoms, an alkenyl group having 2 to 10 carbon atoms, a thiol group, or a hydroxyl group;
at least one R² and/or at least one R³ is a hydroxy group and/or a thiol group;
m² and m³ are each independently an integer of 0 to 8;
m⁴ and m⁵ are each independently an integer of 0 to 9;
n is an integer of 1 to 4; and
p² to p⁵ are each independently an integer of 0 to 2, and

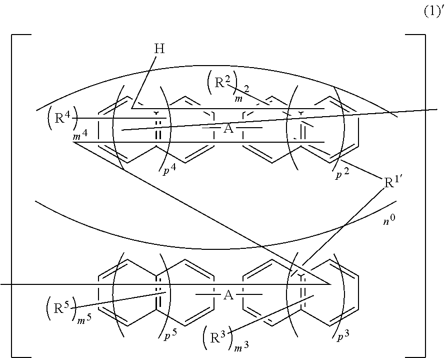

wherein
R^{1′} is a divalent group having 1 to 30 carbon atoms;
n⁰ is an integer of 1 to 10; and
A, R² to R⁵, m² to m⁵, and p² to p⁵ are as defined in the formula (1).
   [2]

The resin according to [1], wherein the formula (1) is the following formula (2):

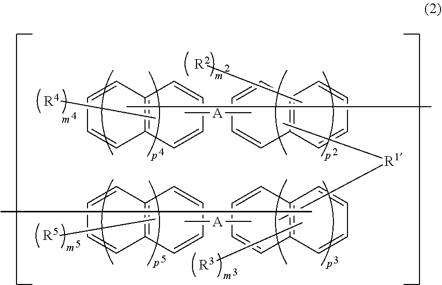

wherein

R^{1′} is a divalent group having 1 to 30 carbon atoms; and

A, R² to R⁵, m² to m⁵, and p² to p⁵ are as defined in the formula (1).

[3]

The resin according to [1] or [2], wherein p² to p⁵ are 0.

[4]

The resin according to any of [1] to [3], wherein A is a single bond.

[5]

The resin according to [1], wherein the formula (1) is the following formula (2a):

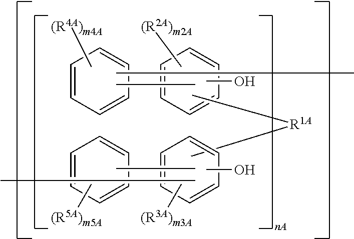

wherein

n^{A} and R^{1A} to R^{5A} are as defined in n and R¹ to R⁵ in the formula (1), respectively;

m^{2A} and m^{3A} are each independently an integer of 0 to 3; and

m^{4A} and m^{5A} are each independently an integer of 0 to 5.

[6]

The resin according to [1], wherein the formula (1) and the formula (1)′ are the following formula (2b) and the following formula (2b)′, respectively:

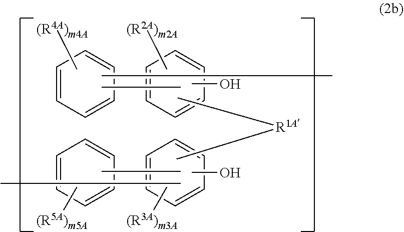

wherein

R^{1A′} is a divalent group having 1 to 30 carbon atoms;

R^{2A} to R^{5A} are as defined in R² to R⁵ in the formula (1), respectively;

m^{2A} and m^{3A} are each independently an integer of 0 to 3; and

m^{4A} and m^{5A} are each independently an integer of 0 to 5, and

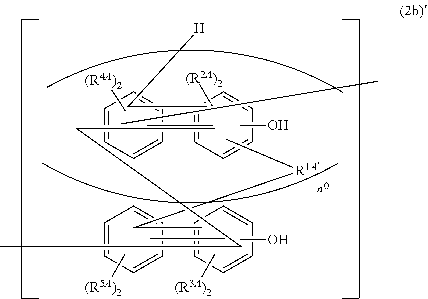

wherein
R^{1A′} is a divalent group having 1 to 30 carbon atoms;
R^{2A} to R^{5A} are as defined in R² to R⁵ in the formula (1), respectively;
m^{2A} and m^{3A} are each independently an integer of 0 to 3;
m^{4A} and m^{5A} are each independently an integer of 0 to 5; and
n⁰ is an integer of 1 to 10.
   [7]

The resin according to [1], wherein the formula (1)′ is the following formula (3a)′ or the following formula (3b)′:

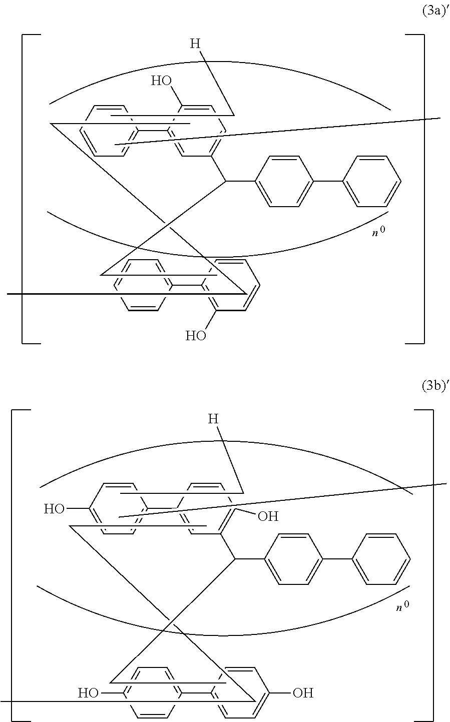

wherein n⁰ is an integer of 1 to 10.
[8]

The resin according to any of [1] to [7], wherein the resin comprises the constituent unit defined in any of [1] to [7], and one or two constituent units different from the constituent unit defined in any of [1] to [7].

[9]

The resin according to any of [1] to [8], further comprising: a constituent unit represented by the following formula (U1) and/or a constituent unit represented by the following formula (U2):

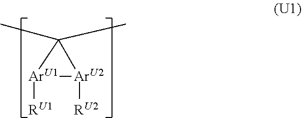

wherein

Ar^{U1} and Ar^{U2} are each independently a phenyl ring or a naphthalene ring; and

R^{U1} and R^{U2} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms, or an alkoxy group having 1 to 10 carbon atoms, and

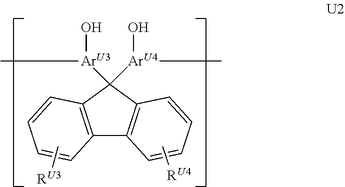

wherein

Ar^{U3} and Ar^{U4} are each independently a phenyl ring or a naphthalene ring; and

R^{U3} and R^{U4} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms or an alkoxy group having 1 to 10 carbon atoms.

[10]

The resin according to [1], wherein the resin comprises a block unit comprising the constituent unit represented by the formula (1) or the formula (1)′, where the block unit is represented by the following formula (4) or the following formula (4)′:

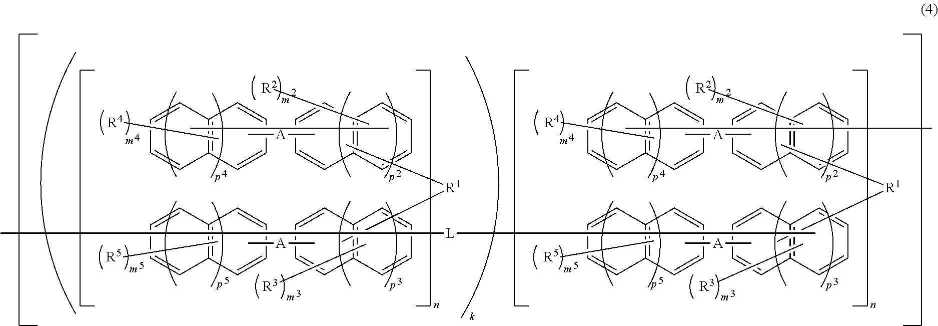

wherein

A, R¹ to R⁵, m² to m⁵, n, and p² to p⁵ are as defined in the formula (1);

L is a divalent group having 1 to 30 carbon atoms or a single bond; and

k is a positive integer, and

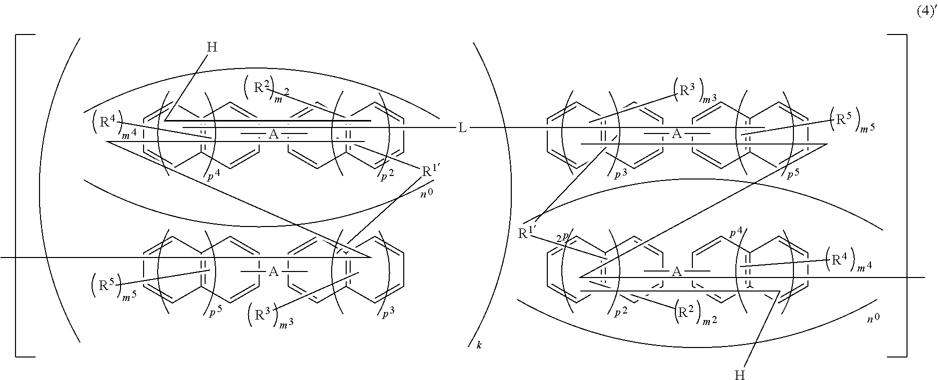

wherein
R^{1′} is a divalent group having 1 to 30 carbon atoms;
A, R² to R⁵, m² to m⁵, and p² to p⁵ are as defined in the formula (1);
L is a divalent group having 1 to 30 carbon atoms or a single bond;
k is a positive integer; and
n⁰ is an integer of 1 to 10.
   [11]

The resin according to [10], wherein the formula (4) is the following formula (5):

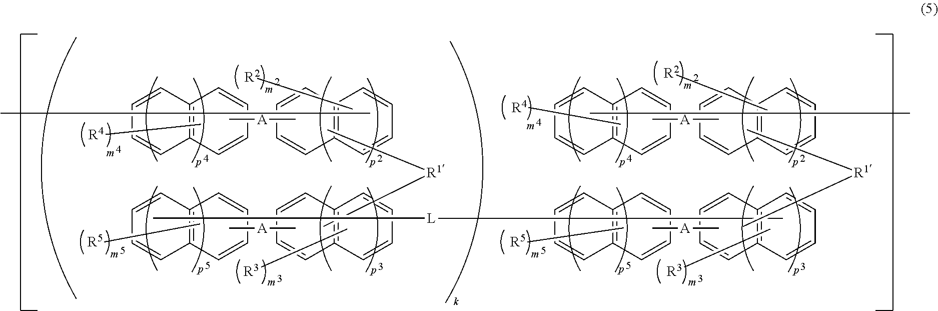

wherein
R^{1′} is a divalent group having 1 to 30 carbon atoms; and
A, R² to R⁵, m² to m⁵, p² to p⁵, L, and k are as defined in the formula (4).
   [12]

The resin according to [10], wherein the formula (4) is the following formula (5a):

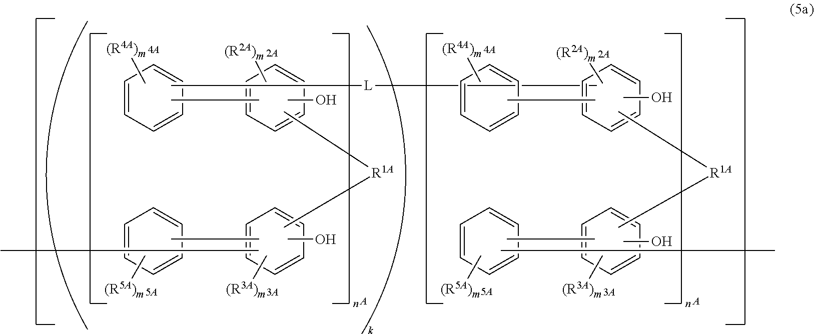

wherein

n^{A}, R^{1A} to R^{5A}, L, and k are as defined in n, R¹ to R⁵, L, and k in the formula (4), respectively;

m^{2A} and m^{3A} are each independently an integer of 0 to 3; and

m^{4A} and m^{5A} are each independently an integer of 0 to 5.

[13]

The resin according to [10], wherein the formula (4) and the formula (4)′ are the following formula (5b) and the following formula (5b)′, respectively:

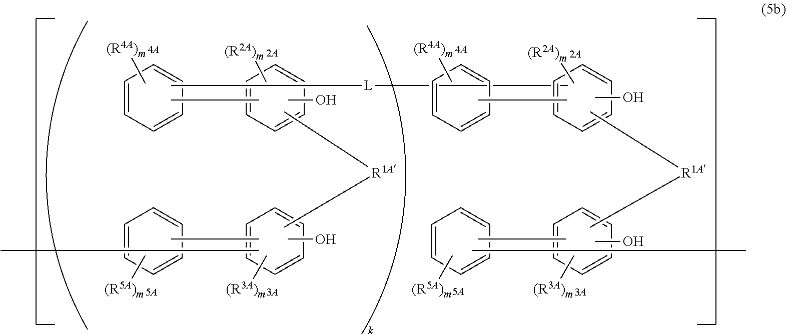

wherein

R^{1A′} is a divalent group having 1 to 30 carbon atoms;

R^{2A} to R^{5A}, L, and k are as defined in R² to R⁵, L, and k in the formula (4), respectively;

m^{2A} and m^{3A} are each independently an integer of 0 to 3; and

m^{4A} and m^{5A} are each independently an integer of 0 to 5, and

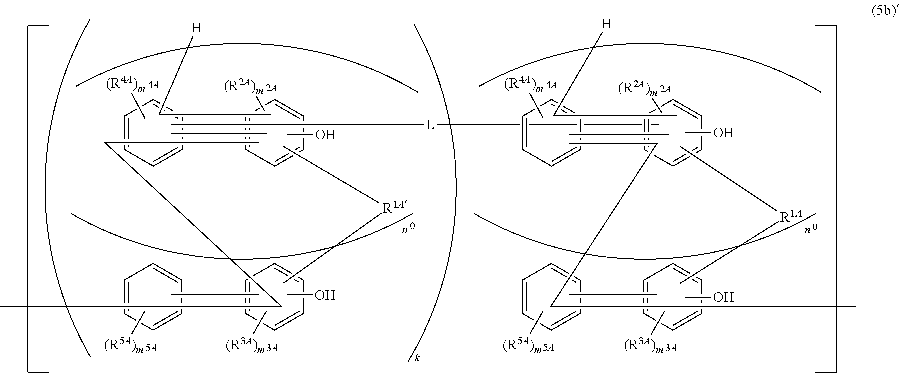

wherein
R^{1A′} is a divalent group having 1 to 30 carbon atoms;
R^{2A} to R^{5A}, L, and k are as defined in R² to R⁵, L, and k in the formula (4), respectively;
m^{2A} and m^{3A} are each independently an integer of 0 to 3;
m^{4A} and m^{5A} are each independently an integer of 0 to 5; and
n⁰ is an integer of 1 to 10.
   [14]

The resin according to any of [10] to [13], wherein the resin comprises the block unit and one or two constituent units different from the constituent units represented by the formula (1) or the formula (1)′.

[15]

The resin according to any of [10] to [14], further comprising: a constituent unit represented by the following formula (U1) and/or a constituent unit represented by the following formula (U2):

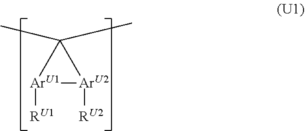

wherein

Ar^{U1} and Ar^{U2} are each independently a phenyl ring or a naphthalene ring; and

R^{U1} and R^{U2} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms, or an alkoxy group having 1 to 10 carbon atoms, and

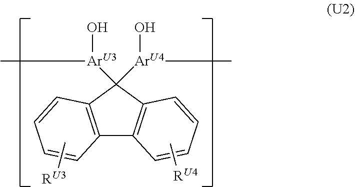

wherein

Ar^{U3} and Ar^{U4} are each independently a phenyl ring or a naphthalene ring; and

R^{U3} and R^{U4} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms or an alkoxy group having 1 to 10 carbon atoms.

[16]

A composition comprising the resin according to any of [1] to [15].

[17]

The composition according to [16], further comprising a solvent.

[18]

The composition according to [16] or [17], further comprising an acid generating agent.

[19]

The composition according to any of [16] to [18], further comprising a crosslinking agent.

[20]

The composition according to any of [16] to [18], wherein the composition is used in film formation for lithography.

[21]

The composition according to [20], wherein the composition is used as a composition for resist film formation.

[22]

The composition according to [20], wherein the composition is used as a composition for underlayer film formation.

[23]

A resist pattern formation method, comprising:
a photoresist layer formation step of forming a photoresist layer on a substrate using the composition according to [21]; and
a development step of irradiating a predetermined region of the photoresist layer formed through the photoresist layer formation step with radiation for development.
   [24]

A resist pattern formation method, comprising:
an underlayer film formation step of forming an underlayer film on a substrate using the composition according to [22];
a photoresist layer formation step of forming at least one photoresist layer on the underlayer film formed through the underlayer film formation step; and
a step of irradiating a predetermined region of the photoresist layer formed through the photoresist layer formation step with radiation for development.
   [25]

A circuit pattern formation method, comprising:
an underlayer film formation step of forming an underlayer film on a substrate using the composition according to [22];
an intermediate layer film formation step of forming an intermediate layer film on the underlayer film formed through the underlayer film formation step;
a photoresist layer formation step of forming at least one photoresist layer on the intermediate layer film formed through the intermediate layer film formation step;
a resist pattern formation step of irradiating a predetermined region of the photoresist layer formed through the photoresist layer formation step with radiation for development, thereby forming a resist pattern;
an intermediate layer film pattern formation step of etching the intermediate layer film with the resist pattern formed through the resist pattern formation step as a mask, thereby forming an intermediate layer film pattern;
an underlayer film pattern formation step of etching the underlayer film with the intermediate layer film pattern formed through the intermediate layer film pattern formation step as a mask, thereby forming an underlayer film pattern; and
a substrate pattern formation step of etching the substrate with the underlayer film pattern formed through the underlayer film pattern formation step as a mask, thereby forming a pattern on the substrate.
   [26]

A method for purifying the resin according to any of [1] to [15], the method comprising:

an extraction step of bringing a solution containing the resin and an organic solvent that does not inadvertently mix with water into contact with an acidic aqueous solution, thereby carrying out extraction.

### Advantageous Effects of Invention

According to the present invention, it is possible to provide a novel resin that is particularly useful as a film forming material for lithography, a composition, a resist pattern formation method, a circuit pattern formation method, and a method for purifying the resin.

### DESCRIPTION OF EMBODIMENTS

Hereinafter, an embodiment of the present invention will be described (hereinafter, referred to as the “present embodiment”). The embodiment described below is given merely for illustrating the present invention. The present invention is not limited only by this embodiment.

### [Resin]

A resin of the present embodiment is a resin containing a constituent unit (repeat unit) represented by the following formula (1) or (1)′. The resin of the present embodiment has, for example, the following characteristics (1) to (3).
(1) The resin of the present embodiment has excellent solubility in an organic solvent (particularly, a safe solvent). Therefore, for example, when the resin of the present embodiment is used as a film forming material for lithography, films for lithography can be formed by a wet process such as spin coating or screen printing.
(2) In the resin of the present embodiment, the carbon concentration is relatively high and the oxygen concentration is relatively low. In addition, since the resin of the present embodiment has a phenolic hydroxy group and/or a phenolic thiol group in the molecule, it is useful for formation of a cured product through the reaction with a curing agent, but it can also form a cured product on its own through the crosslinking reaction of the phenolic hydroxy group and/or the phenolic thiol group upon baking at a high temperature. Due to the above, the resin of the present embodiment can exhibit high heat resistance, and when the resin of the present embodiment is used as a film forming material for lithography, degradation of the film upon baking at a high temperature is suppressed and a film for lithography excellent in etching resistance to oxygen plasma etching and the like can be formed.
(3) The resin of the present embodiment can exhibit high heat resistance and etching resistance, as described above, and also has excellent adhesiveness to a resist layer and a resist intermediate layer film material. Therefore, when the resin of the present embodiment is used as a film forming material for lithography, films for lithography excellent in resist pattern formability can be formed. The term “resist pattern formability” herein refers to a property in which there are no major defects in the resist pattern shape and both resolution and sensitivity are excellent.

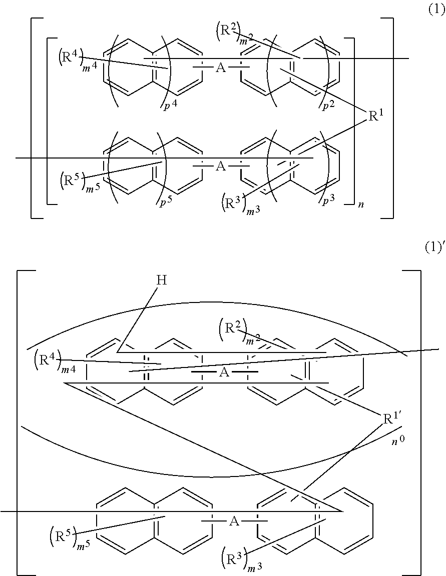

In the above formula (1) or (1)′, A is a single bond, an alkylene having 1 to 4 carbon atoms and optionally having a substituent, or a heteroatom; R¹ is a 2n-valent group having 1 to 30 carbon atoms; R^{1′} is as R¹ in which n of the 2n-valent group is 1; R² to R⁵ are each independently a linear alkyl group having 1 to 10 carbon atoms, a branched alkyl group having 3 to 10 carbon atoms, a cyclic alkyl group having 3 to 10 carbon atoms, an aryl group having 6 to 10 carbon atoms, an alkenyl group having 2 to 10 carbon atoms, a thiol group, or a hydroxyl group; at least one R² and/or at least one R³ is a hydroxy group and/or a thiol group; m² and m³ are each independently an integer of 0 to 8; m⁴ and m⁵ are each independently an integer of 0 to 9; n is an integer of 1 to 4; p² to p⁵ are each independently an integer of 0 to 2; and n⁰ is an integer of 1 to 10.

In the formula (1) or (1)′, A is a single bond, an alkylene having 1 to 4 carbon atoms and optionally having a substituent, or a heteroatom, and a heteroatom is an atom other than a carbon atom and a hydrogen and is an atom capable of forming a divalent group, such as a sulfur atom and an oxygen atom. From the viewpoint of etching resistance, A is preferably a single bond or a heteroatom, and still more preferably a single bond.

In the formula (1), R¹ is a 2n-valent group having 1 to 30 carbon atoms, and each aromatic ring is bonded via this R¹. Specific examples of the 2n-valent group will be mentioned later.

In the formula (1) or (1)′, R² to R⁵ are each independently a monovalent group selected from the group consisting of a linear alkyl group having 1 to 10 carbon atoms, a branched alkyl group having 3 to 10 carbon atoms, a cyclic alkyl group having 3 to 10 carbon atoms, an aryl group having 6 to 10 carbon atoms, an alkenyl group having 2 to 10 carbon atoms, a thiol group, and a hydroxyl group. Examples of the alkyl group include a linear or branched alkyl group such as a methyl group, an ethyl group, an n-propyl group, an isopropyl group, an n-butyl group, an iso-butyl group, a sec-butyl group, a tert-butyl group, a pentyl group, and a hexyl group; and a cyclic alkyl group such as a cyclopentyl group and a cyclohexyl group. Examples of the aryl group include a phenyl group, a naphthyl group, a tolyl group, and a xylyl group. Examples of the alkenyl group include an ethenyl group, a propenyl group, a butenyl group, a pentenyl group, and a hexenyl group. However, at least one R² and/or at least one R³ is a hydroxy group and/or a thiol group.

In the formula (1) or (1)′, m² and m³ are each independently an integer of 0 to 8, preferably an integer of 0 to 4, and more preferably 1 or 2. m⁴ and m⁵ are each independently an integer of 0 to 9, preferably an integer of 0 to 4, and still more preferably 1 or 2.

In the formula (1), n is an integer of 1 to 4, preferably an integer of 1 to 2, and still more preferably 1.

In the formula (1) or (1)′, p² to p⁵ are each independently an integer of 0 to 2, preferably an integer of 0 or 1, and still more preferably 0.

In the formula (1)′, n⁰ is an integer of 1 to 10, preferably an integer of 1 to 5, and still more preferably an integer of 1 to 4.

Examples of the 2n-valent group R¹ include a divalent hydrocarbon group having 1 to 30 carbon atoms (for example, a linear or branched hydrocarbon group or a cyclic hydrocarbon group, such as an alkylene group) when n is 1; a tetravalent hydrocarbon group having 1 to 30 carbon atoms (for example, a linear or branched hydrocarbon group or a cyclic hydrocarbon group, such as an alkanetetrayl group) when n is 2; a hexavalent hydrocarbon group having 2 to 30 carbon atoms (for example, a linear or branched hydrocarbon group or a cyclic hydrocarbon group, such as an alkanehexayl group) when n is 3; and an octavalent hydrocarbon group having 3 to 30 carbon atoms (for example, a linear or branched hydrocarbon group or a cyclic hydrocarbon group, such as an alkaneoctayl group) when n is 4. Here, the above cyclic hydrocarbon group may have a bridged cyclic hydrocarbon group or an aromatic group.

Also, the above 2n-valent group (for example, a 2n-valent hydrocarbon group) may have a double bond or may have a heteroatom.

R¹ is preferably a 2n-valent hydrocarbon group having an aryl group having 6 to 30 carbon atoms (preferably 6 to 14 carbon atoms) and optionally having a substituent. The 2n-valent hydrocarbon is preferably a methylene group. The aryl group having 6 to 30 carbon atoms (preferably 6 to 14 carbon atoms) is preferably a phenyl group, a biphenyl group, or a naphthyl group.

Since the repeat unit represented by the above formula (1) or (1)′ has a hydroxyl group and/or a thiol group, the resin containing the repeat unit represented by the above formula (1) or (1)′ has high solubility in an organic solvent (particularly a safe solvent). Further, since the repeat unit represented by the above formula (1) or (1)′ has high heat resistance due to rigidity of the structure, the resin containing the repeat unit represented by the above formula (1) or (1)′ can be used even under high-temperature baking conditions. Further, since a resin having a relatively high carbon concentration is obtained, high etching resistance can also be exhibited.

Furthermore, the repeat unit represented by the above formula (1) or (1)′ has a tertiary carbon or a quaternary carbon in the molecule, and the resin containing the repeat unit represented by the above formula (1) or (1)′ is suppressed in crystallization and is suitably used as a film forming material for lithography.

In the repeat unit represented by the above formula (1) or (1)′, it is preferable that at least one R² and/or at least one R³ be a hydroxy group and/or a thiol group from the viewpoint of easy crosslinking reaction and solubility in organic solvents of the resin containing the repeat unit represented by the above formula (1) or (1)′.

The resin containing a repeat unit represented by the above formula (1) or (1)′ preferably further contains a repeat unit different from the repeat unit represented by the above formula (1) or (1)′ in order to balance the properties required for a resin for lithography. It is preferable that there be one or two of repeat units different from the repeat unit represented by the above formula (1) or (1)′.

Examples of the properties required for a resin for lithography include solubility in an organic solvent, solubility in a developing solution or a stripping solution, the amount of change in solubility before and after exposure, film formability, etching resistance, and smoothing properties.

Examples of the repeat unit different from the repeat unit represented by the above formula (1) or (1)′ include, but are not limited to, repeat units represented by the following formulas (U1) and (U2).

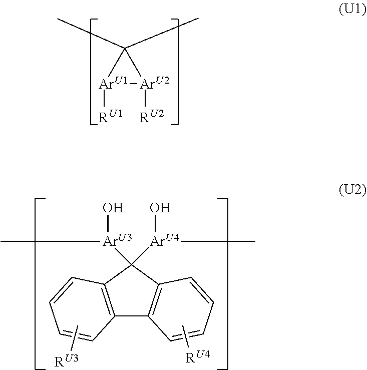

In the above formulas (U1) and (U2), Ar^{U1} to Ar^{U4} represent a phenyl ring or a naphthalene ring (preferably a phenyl ring), and R^{U1} to R^{U4} represent a hydrogen atom or an alkyl group having 1 to 10 carbon atoms which may have a branched or cyclic structure, a unsaturated bond, or a heteroatom (for example, a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms, or an alkoxy group having 1 to 10 carbon atoms, preferably a hydrogen atom).

The molar ratio of the repeat unit represented by the formula (1) or (1)′ to the repeat unit represented by the formula (U1) may be, for example, 1:1.5 to 3.5, 1:2.0 to 3.0, or the like.

The molar ratio of the repeat unit represented by the formula (1) or (1)′ to the repeat unit represented by the formula (U2) may be, for example, 1:0.5 to 2.0, 1:0.5 to 1.5, or the like.

Specific examples of the above formula (U1) include, but are not limited to, the following:

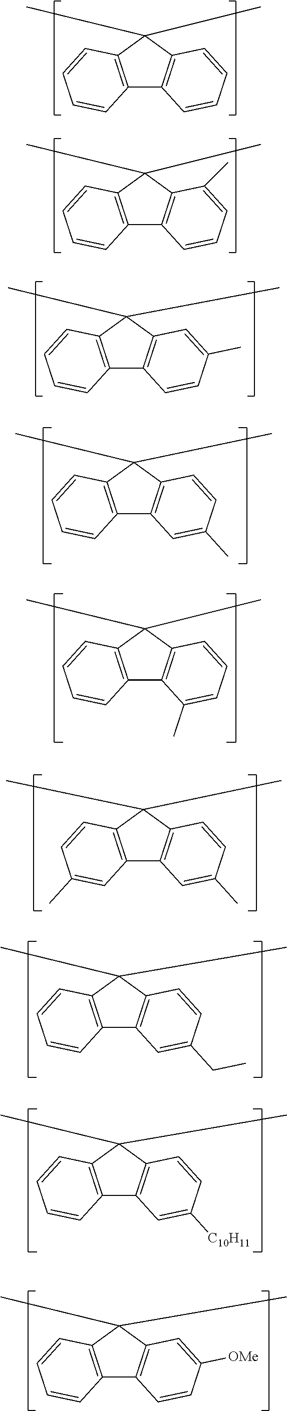

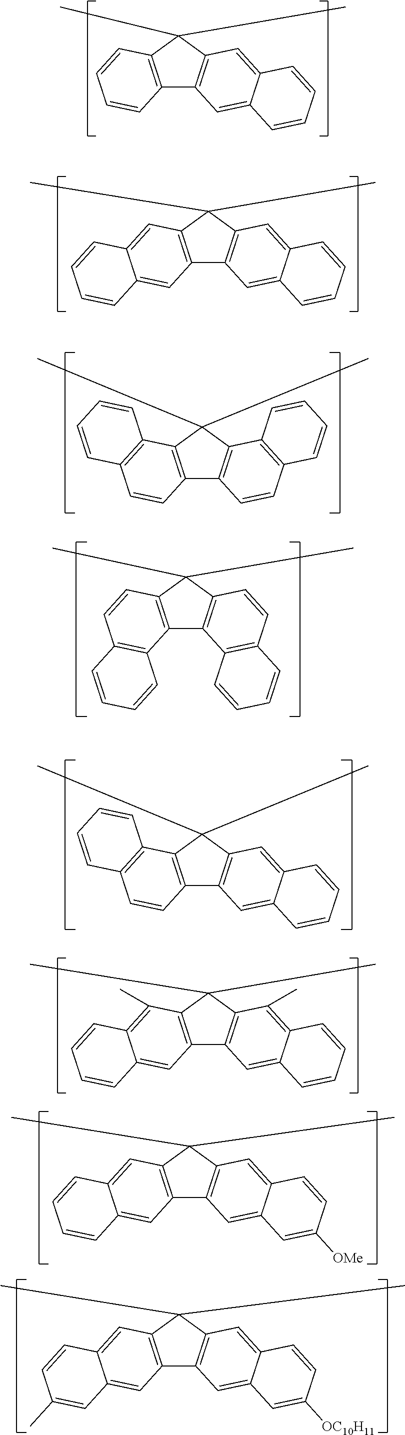

Specific examples of the above formula (U2) include, but are not limited to, the following:

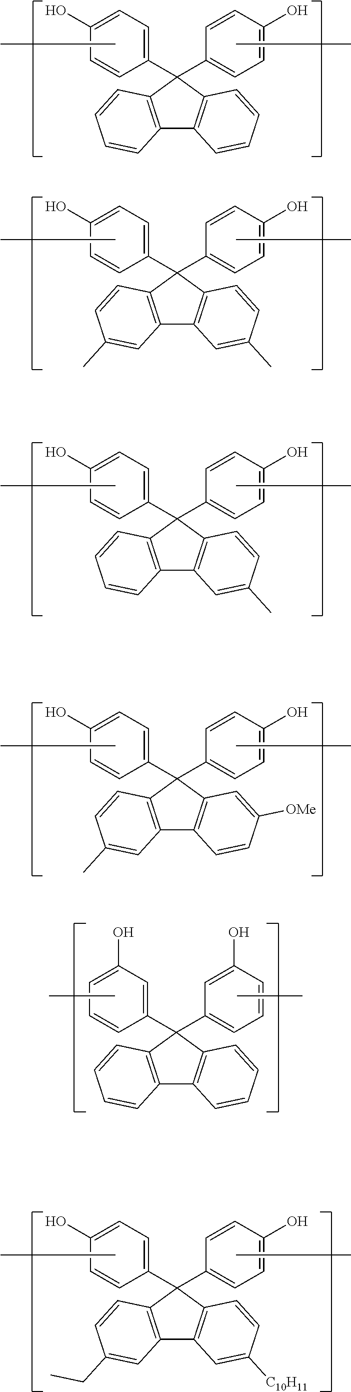

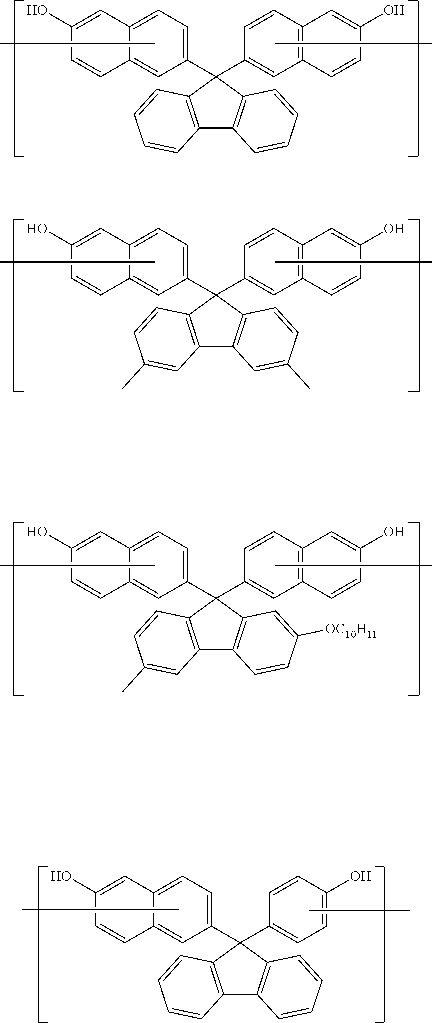

The formula (1) is preferably the formula (2) from the viewpoint of ease of crosslinking and solubility in an organic solvent.

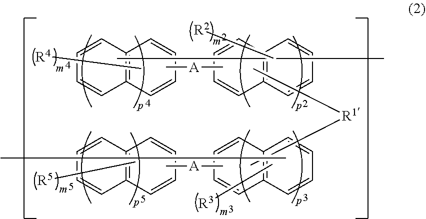

In the above formula (2), R^{1′} is a divalent group having 1 to 30 carbon atoms, specifically those described as R¹ in the formula (1).

A, R² to R⁵, m², m³, m⁴, m⁵, and p² to p⁵ are as described in the formula (1).

The formula (1) is also preferably the following formula (2a) or (2b) from the viewpoint of the supply of raw materials.

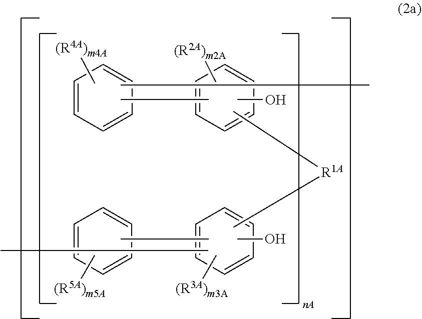

In the above formula (2a), n^{A} and R^{1A} to R^{5A} are as defined in n and R¹ to R⁵ in the formula (1), respectively. m^{2A} and m^{3A} are each independently an integer of 0 to 3. m^{4A} and m^{5A} are each independently an integer of 0 to 5.

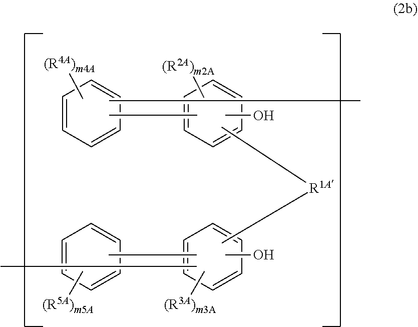

In the above formula (2b), R^{1A′} is a divalent group having 1 to 30 carbon atoms, specifically those described as R¹ in the formula (1). R^{2A} to R^{5A} are as defined in R² to R⁵ in the formula (1), respectively. m^{2A} and m^{3A} are each independently an integer of 0 to 3. m^{4A} and m^{5A} are each independently an integer of 0 to 5.

Further, specific examples of the compound constituting the repeat unit represented by the formula (2a) or (2b) include, but are not limited to, the following compounds:

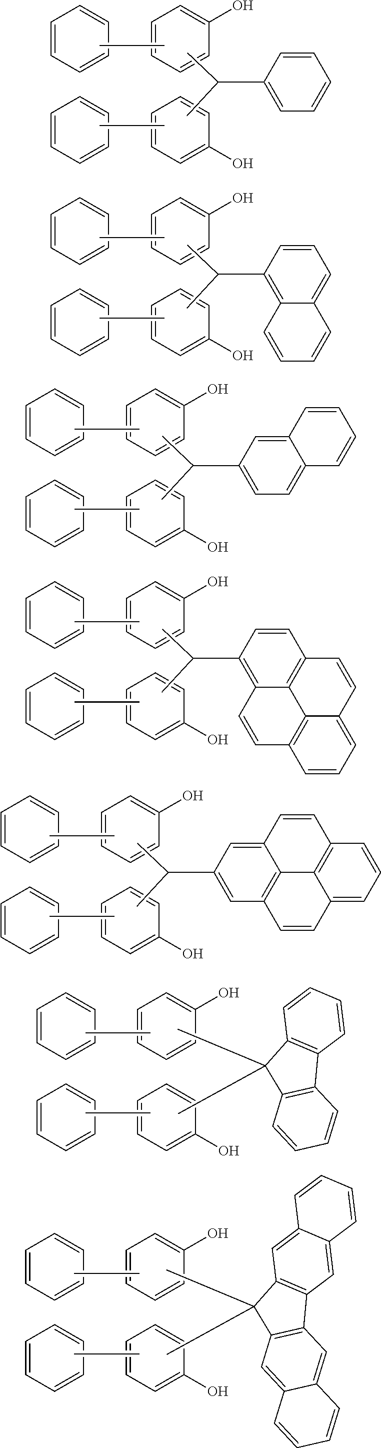

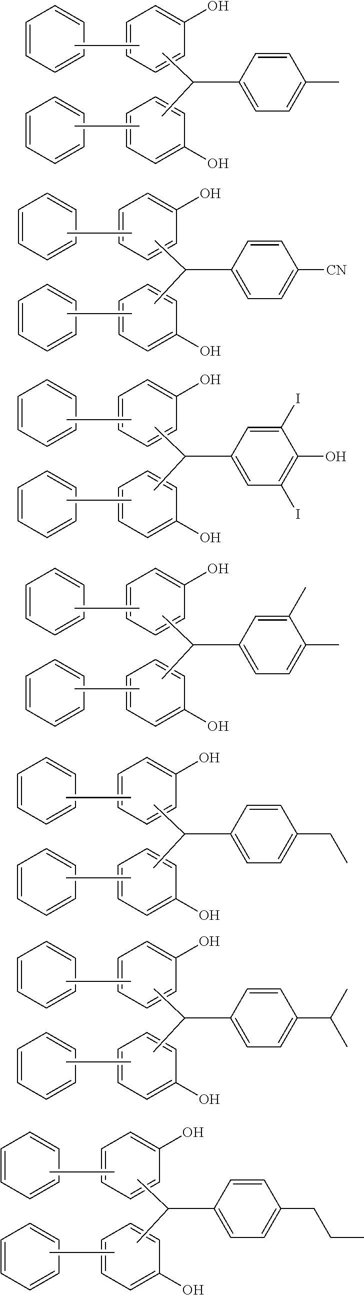

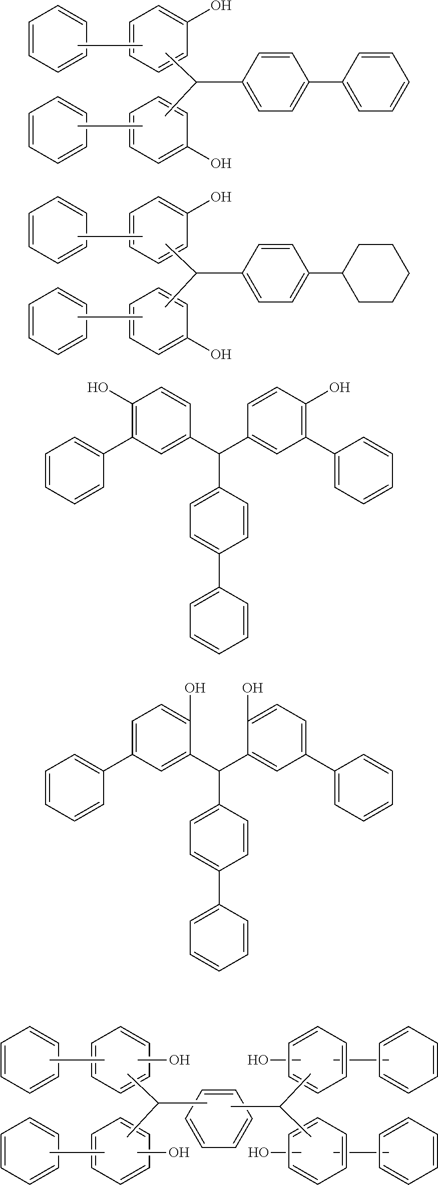

From the viewpoint of the supply of raw materials, the formula (1)′ is preferably represented by the following formula (2b)′, (3a)′, or (3b)′.

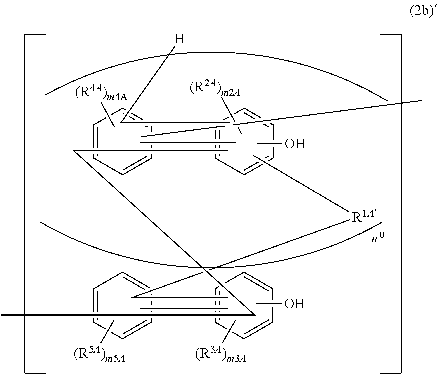

wherein R^{1A′} is a divalent group having 1 to 30 carbon atoms, specifically those described as R¹ in the formula (1); R^{2A} to R^{5A} are as defined in R² to R⁵ in the formula (1), respectively; m^{2A} and m^{3A} are each independently an integer of 0 to 3; m^{4A} and m^{5A} are each independently an integer of 0 to 5; and n⁰ is as described in the formula (1)′.

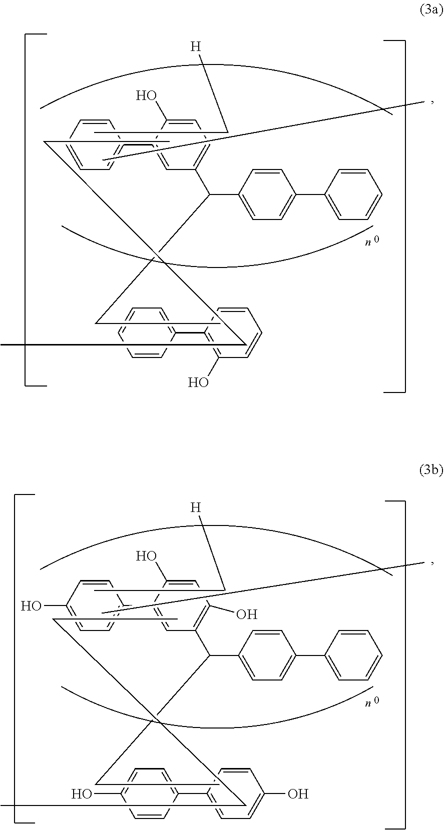

wherein n⁰ is as described in the formula (1)′.

Specific examples of the formula (3a)′ or (3b)′ include, but are not limited to, the following (the definition of n⁰ is as described in the formula (1)′).

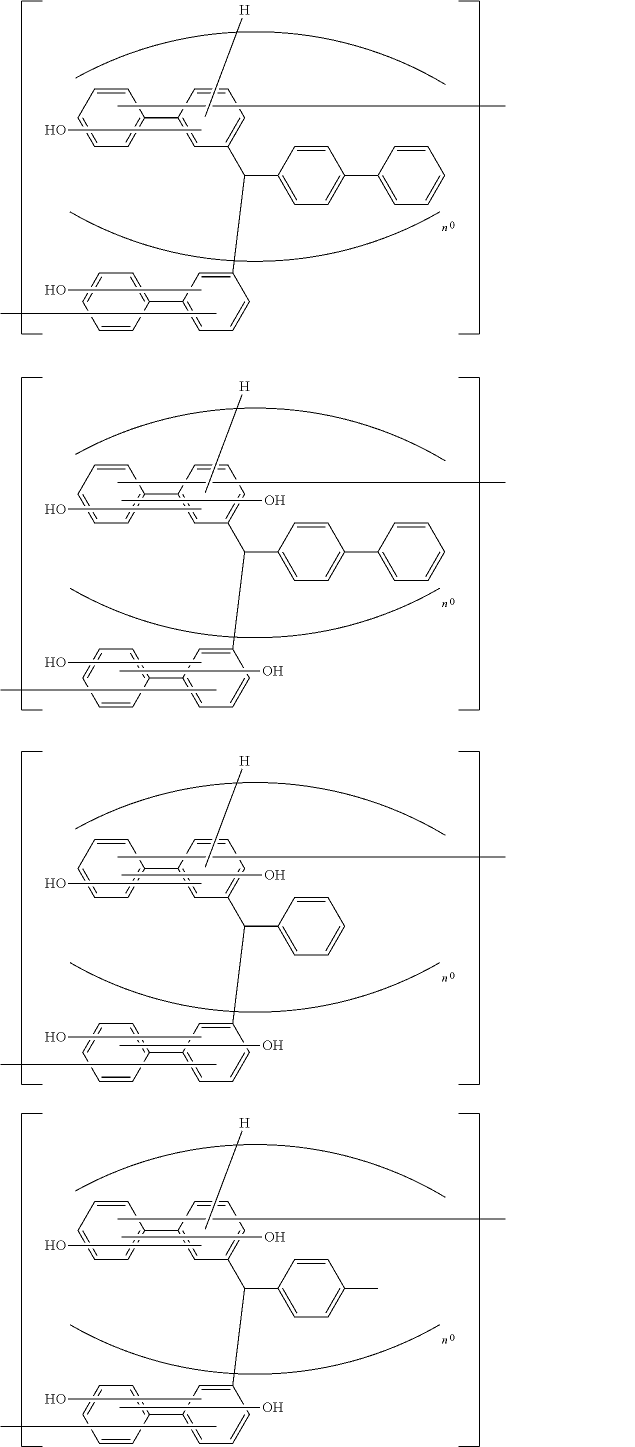

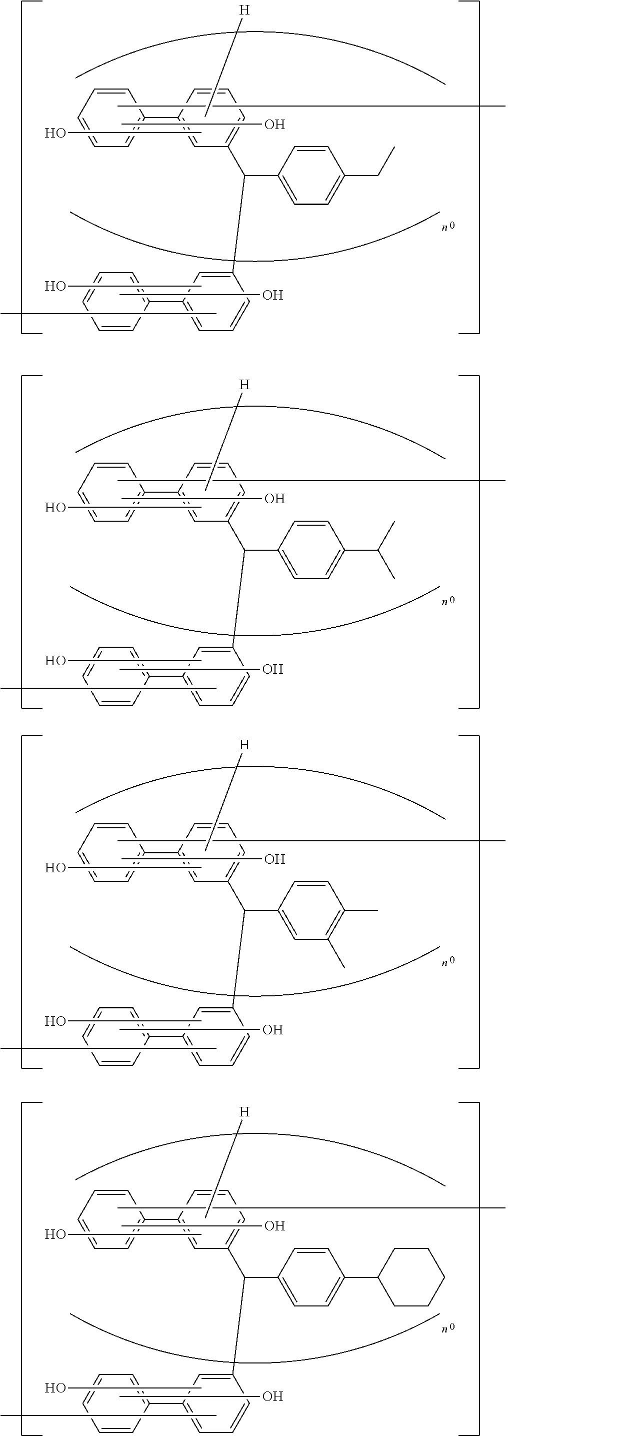

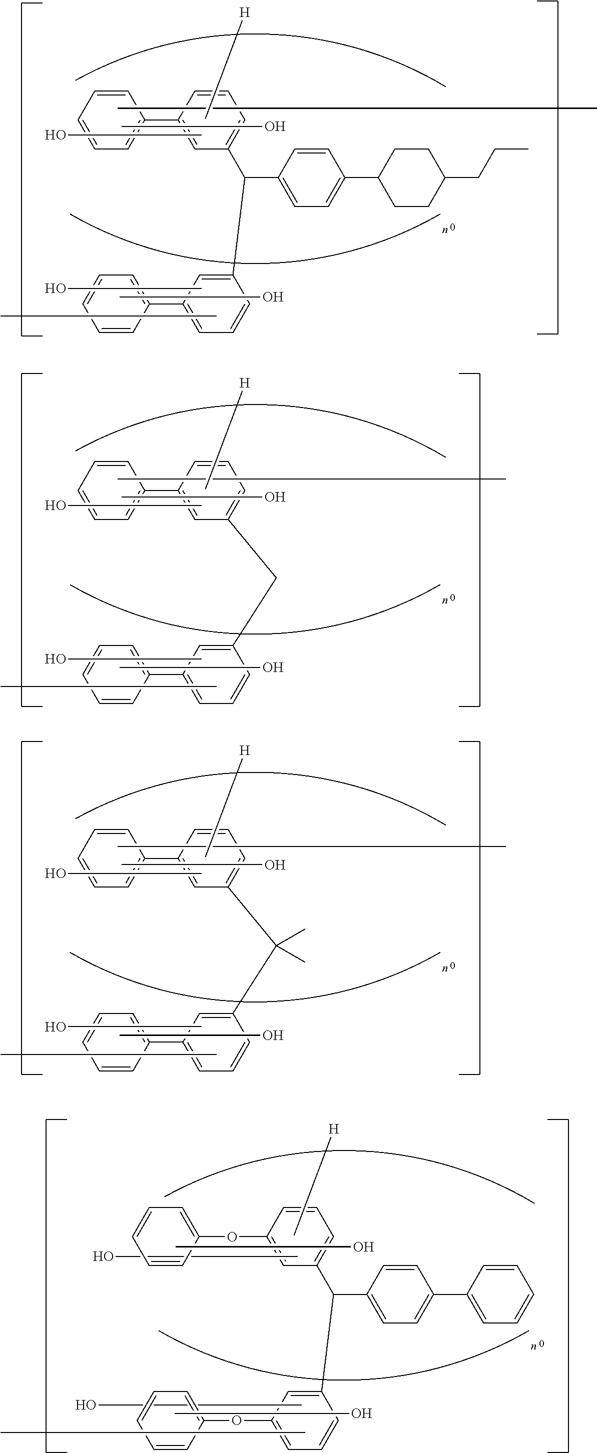

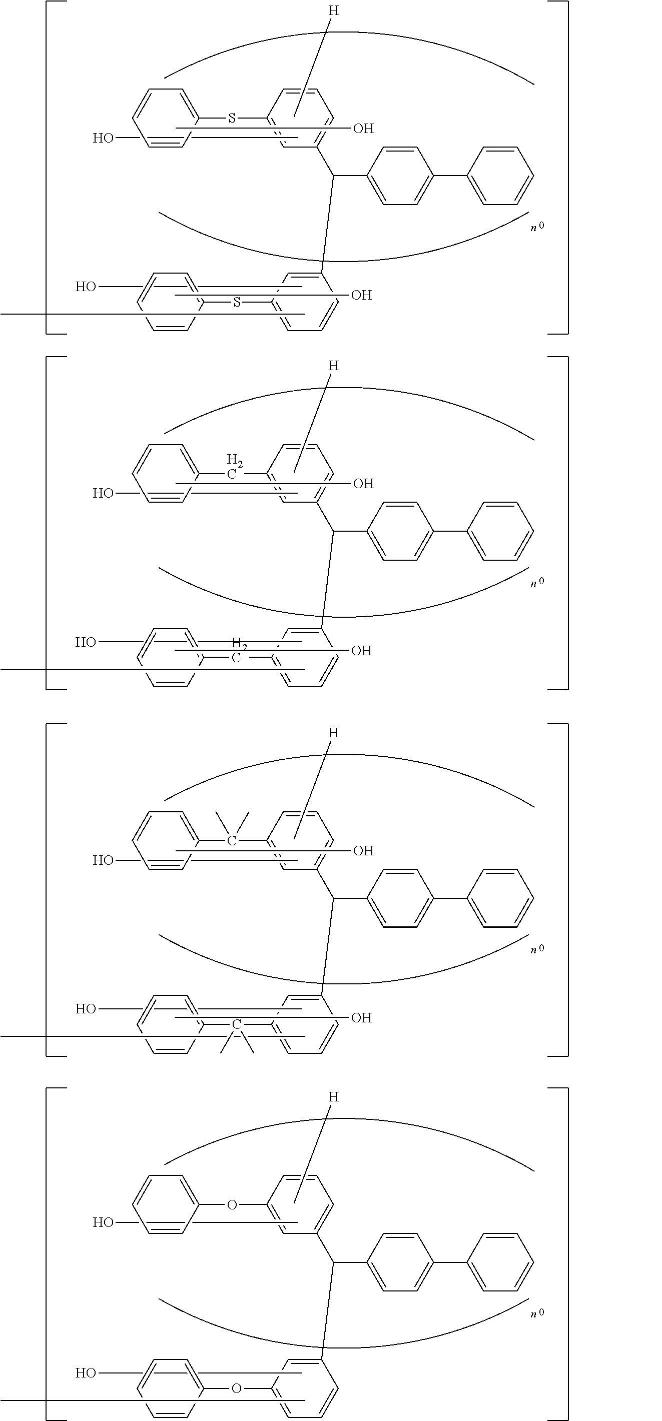

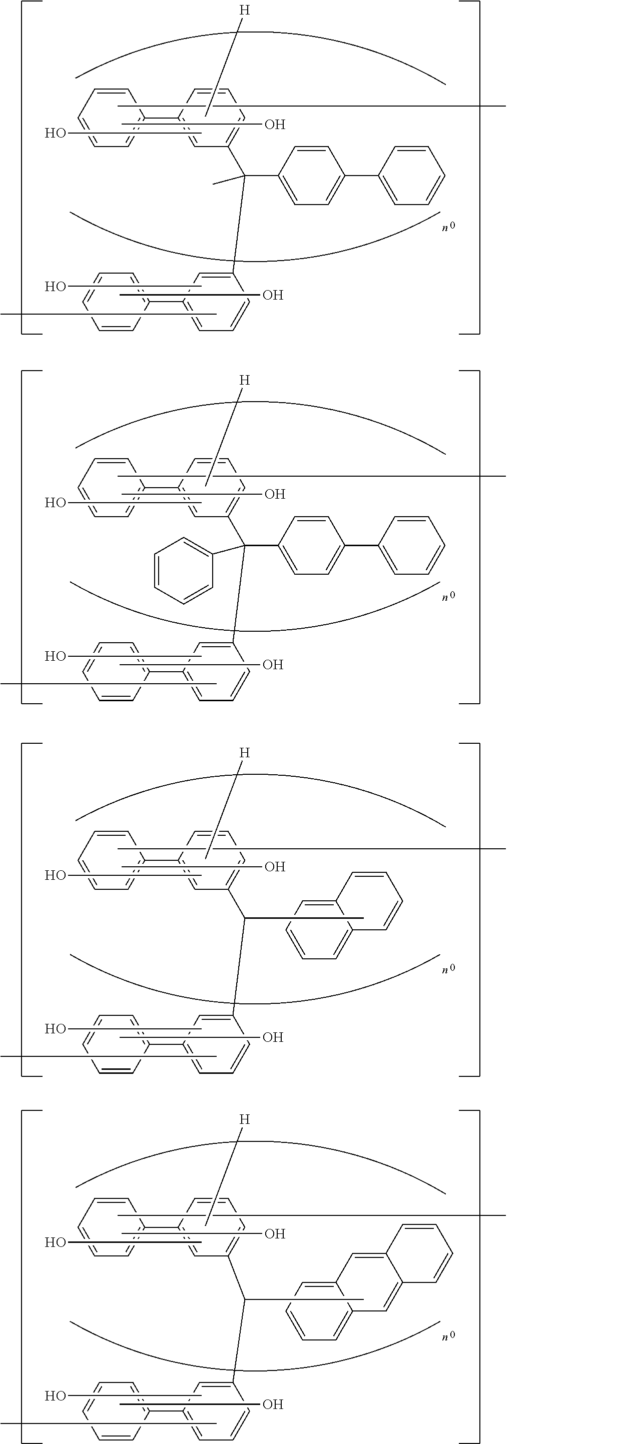

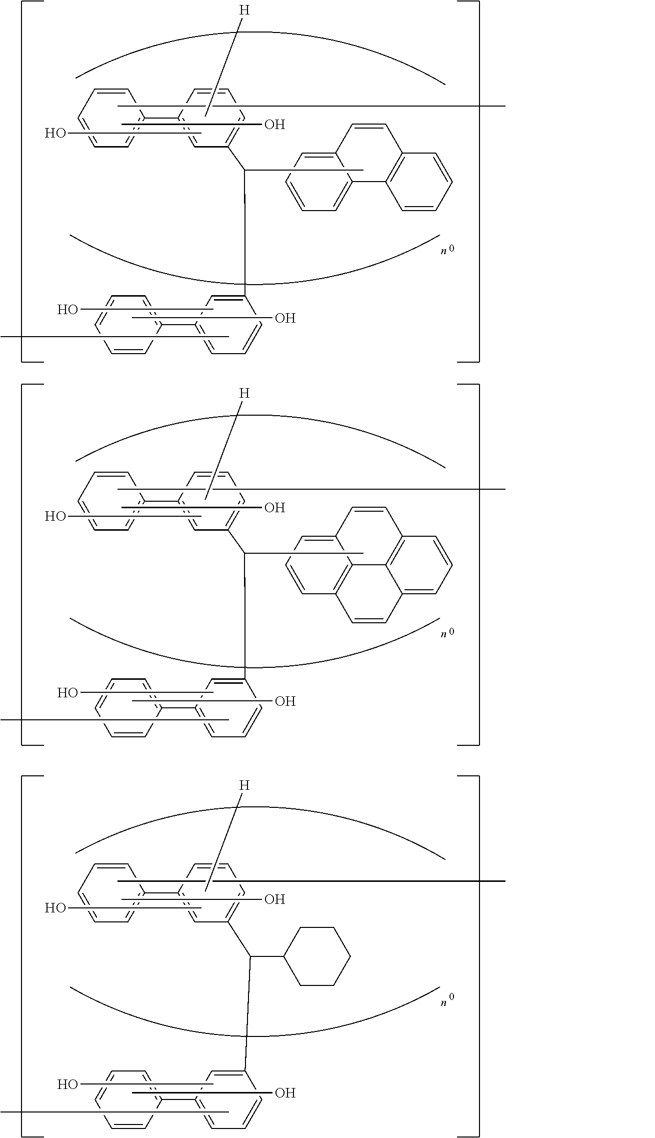

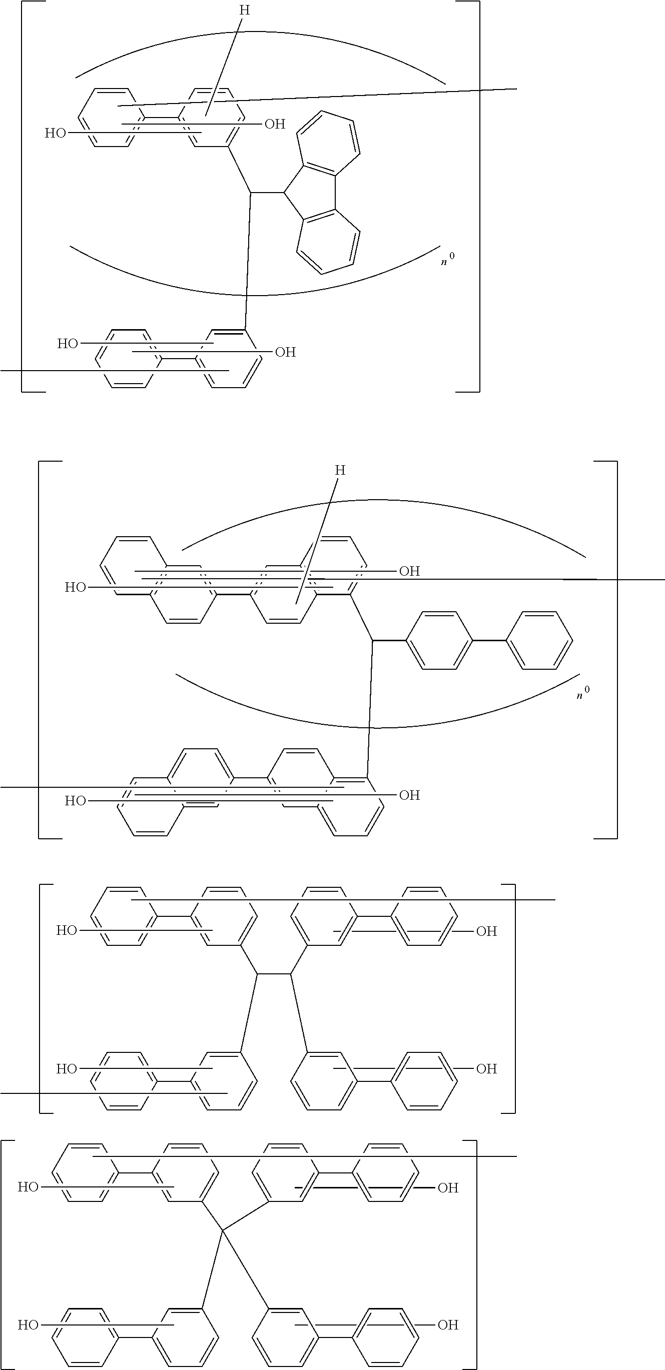

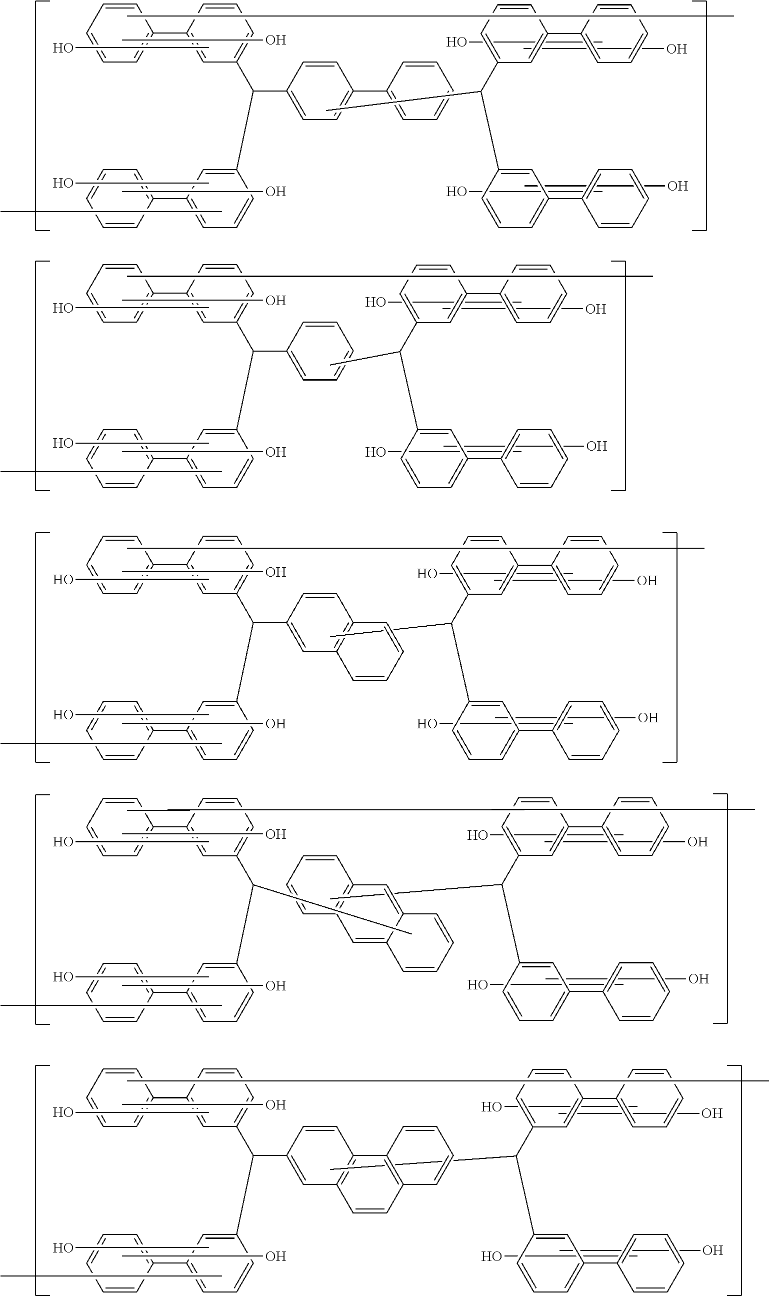

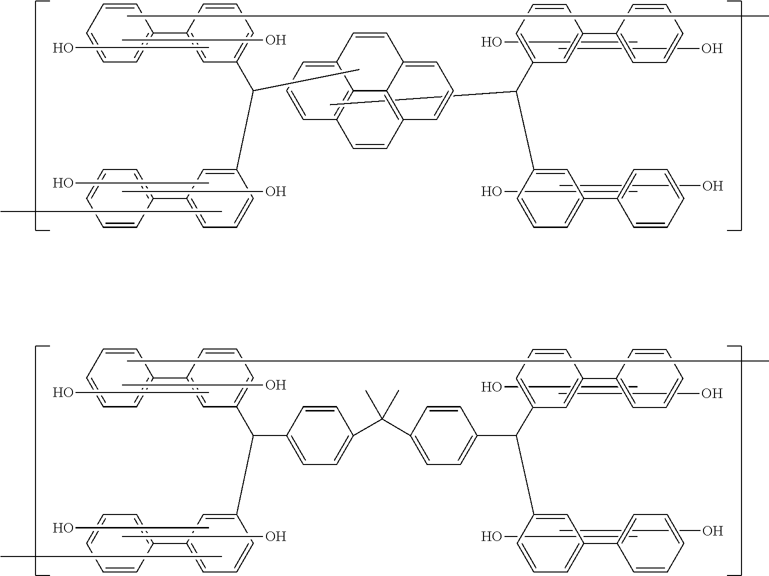

The resin of the present embodiment preferably contains a block unit containing a constituent unit represented by the above formula (1) or (1)′ or the like. From the viewpoint of the supply of raw materials, the block unit is preferably represented by the following formula (4), (4)′, (5), (5a), (5b), or (5b)′.

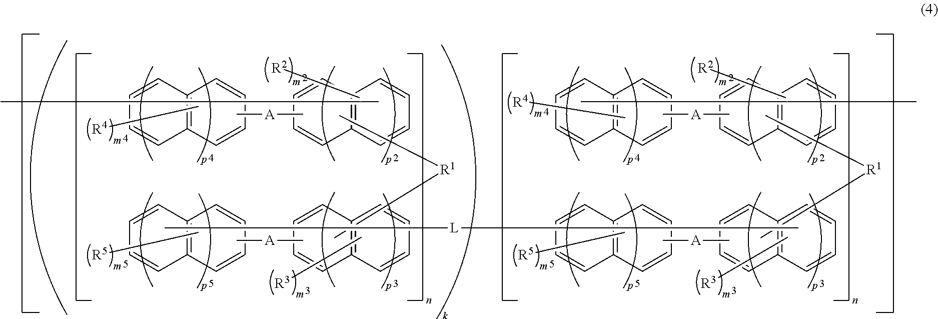

In the formula (4), A, R¹ to R⁵, m² to m⁵, n, and p² to p⁵ are as described in the formula (1). L is a divalent group having 1 to 30 carbon atoms or a single bond. k is a positive integer.

L is preferably a 2n-valent hydrocarbon group having an aryl group having 6 to 30 carbon atoms (preferably 6 to 14 carbon atoms) and optionally having a substituent. The 2n-valent hydrocarbon is preferably a methylene group. The aryl group having 6 to 30 carbon atoms (preferably 6 to 14 carbon atoms) is preferably a phenyl group, a biphenyl group, or a naphthyl group.

k is preferably an integer of 1 to 30, more preferably an integer of 2 to 30, and still more preferably an integer of 2 to 20.

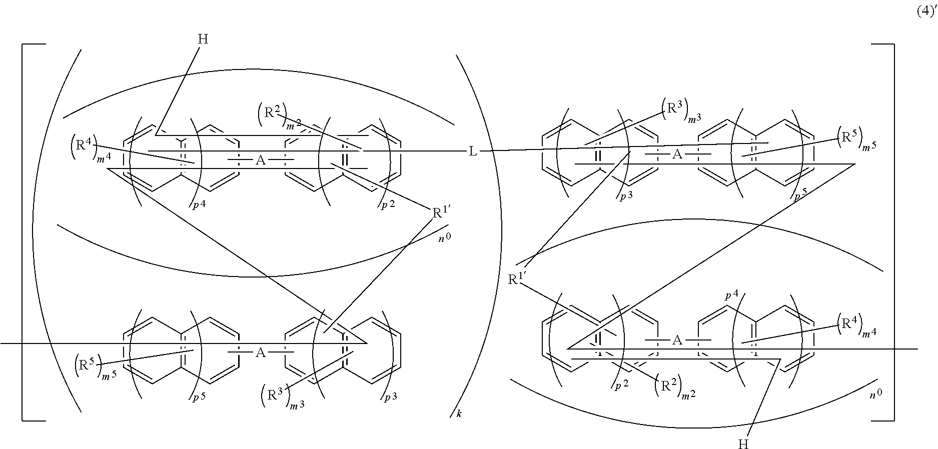

wherein

R^{1′} is a divalent group having 1 to 30 carbon atoms, specifically those described as R¹ in the formula (1); A, R² to R⁵, m² to m⁵, and p² to p⁵ are as defined in the formula (1); L and k are as described in the formula (4) and n⁰ is as described in the formula (1)′.

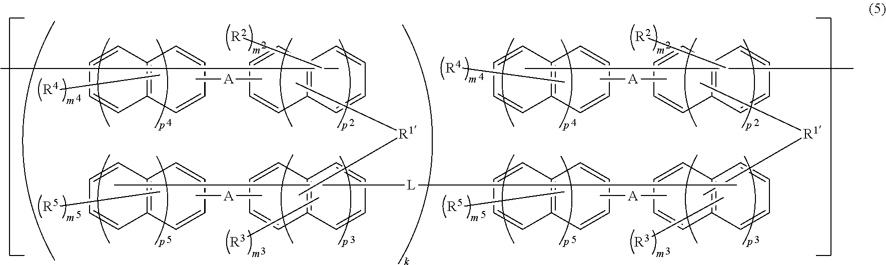

wherein

R^{1′} is a divalent group having 1 to 30 carbon atoms, specifically those described as R¹ in the formula (1); and A, R² to R⁵, m² to m⁵, p² to p⁵, L, and k are as defined in the formula (4).

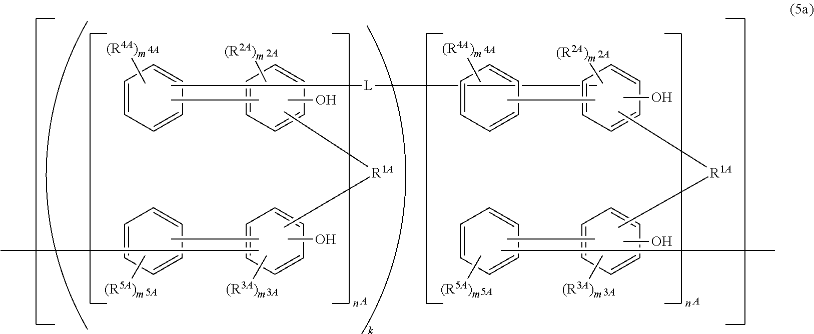

wherein n^{A}, R^{1A} to R^{5A}, L, and k are as defined in n, R¹ to R⁵, L, and k in the formula (4), respectively; m^{2A} and m^{3A} are each independently an integer of 0 to 3; and m^{4A} and m^{5A} are each independently an integer of 0 to 5.

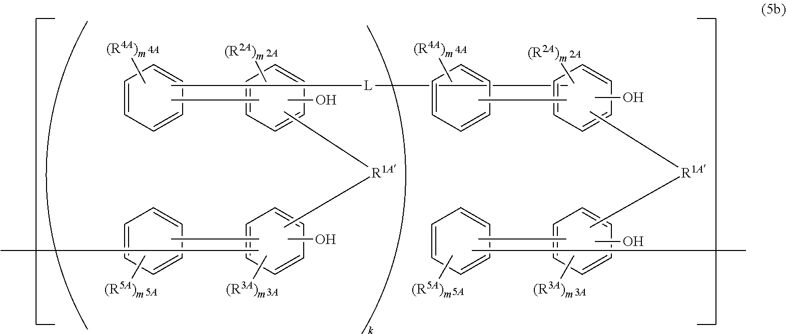

wherein R^{1A′} is a divalent group having 1 to 30 carbon atoms, specifically those described as R¹ in the formula (1); R^{2A} to R^{5A}, L, and k are as defined in R² to R⁵, L, and k in the formula (4), respectively; m^{2A} and m^{3A} are each independently an integer of 0 to 3; and m^{4A} and m^{5A} are each independently an integer of 0 to 5.

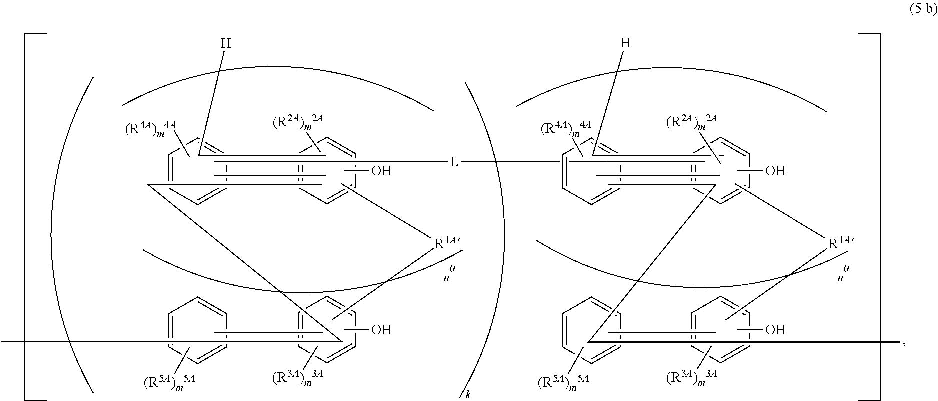

wherein R^{1A′} is a divalent group having 1 to 30 carbon atoms, specifically those described as R¹ in the formula (1); R^{2A} to R^{5A}, L, and k are as defined in R² to R⁵, L, and k in the formula (4), respectively; m^{2A} and m^{3A} are each independently an integer of 0 to 3; m^{4A} and m^{5A} are each independently an integer of 0 to 5; and n⁰ is as described in the formula (1)′.

In addition to the block unit, the resin of the present embodiment preferably further contains a repeat unit represented by the above formula (U1) and/or (U2).

The molar ratio of the block unit to the repeat unit represented by the formula (U1) may be, for example, 1:1.5 to 3.5, 1:2.0 to 3.0, or the like.

The molar ratio of the block unit to the repeat unit represented by the formula (U2) may be, for example, 1:0.5 to 2.0, 1:0.5 to 1.5, or the like.

Examples of the method for synthesizing a compound from which the repeat unit represented by the formula (1) is derived include the following method. That is, the compound from which the repeat unit represented by the above formula (1) is derived is obtained through a polycondensation reaction among the compound represented by the following formula (1-x), the compound represented by the following formula (1-y), and the compound represented by the following formula (z1) in the presence of an acid catalyst or base catalyst at normal pressure. If necessary, the above reaction may be carried out under increased pressure.

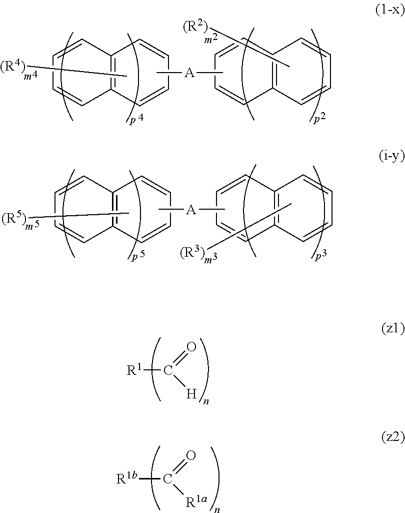

In the above formula (1-x), A, R², R⁴, m², m⁴, p² and p⁴ are as defined in A, R², R⁴, m², m⁴, p² and p⁴ in the formula (1), respectively; in the above formula (1-y), A, R³, R⁵, m³, m⁵, p³ and p⁵ are as defined in A, R³, R⁵, m³, m⁵, p³ and p⁵ in the formula (1), respectively; and the compound represented by the above formula (1-x) may be the same as the compound represented by the above formula (1-y).

In the above formulas (z1) and (z2), n is as defined in n in the above formula (1), and in the above formulas (z1) and (z2), the “R¹—C—H” moiety and the “R^{1b}—C—R^{1a}” moiety each corresponds to R¹ in the above formula (1)

As a specific example of the above polycondensation reaction, the compound from which the repeat unit represented by the above formula (1) is derived is obtained through a polycondensation reaction between a dihydroxyphenyl ether, a dihydroxyphenyl thioether, a dihydroxynaphthyl ether, a dihydroxynaphthyl thioether, a dihydroxyanthracyl ether or a dihydroxyanthracyl thioether and a corresponding aldehyde or ketone in the presence of an acid catalyst or base catalyst, and optionally in the presence of a reaction solvent. Here, specific examples, amounts to be used, and the like of a dihydroxyphenyl ether, a dihydroxyphenyl thioether, a dihydroxynaphthyl ether, a dihydroxynaphthyl thioether, a dihydroxyanthracyl ether, a dihydroxyanthracyl thioether, an aldehyde, a ketone, an acid catalyst, a base catalyst, and a reaction solvent include those described in International Publication No. WO 2020/026879 and International Publication No. WO 2019/151400.

The reaction temperature in the above reaction can be arbitrarily selected according to the reactivity of the reaction raw materials and is not particularly limited, and is usually within the range of 10 to 200° C.

In order to obtain the compound from which the repeat unit represented by the formula (1) is derived of the present embodiment, a higher reaction temperature is preferable. Specifically, the range of 60 to 200° C. is preferable. Although the reaction method is not particularly limited, for example, the raw materials (reactants) and the catalyst may be charged in a batch, or the raw materials (reactants) may be dripped successively in the presence of the catalyst. After the polycondensation reaction terminates, isolation of the obtained compound can be performed according to a conventional method, and is not particularly limited. For example, by adopting a commonly used approach in which the temperature of the reaction vessel is elevated to 130 to 230° C. in order to remove unreacted raw materials, catalyst, etc. present in the system, and volatile portions are removed at about 1 to 50 mmHg, the compound that is the objective product can be obtained.

Examples of the preferable reaction conditions include conditions under which the reaction proceeds by using 1.0 mol to an excess of the compound represented by the above formula (1-x) and the compound represented by the above formula (1-y) based on 1 mol of the aldehyde or the ketone represented by the above formula (z1) or (z2), further using 0.001 to 1 mol of the acid catalyst, and reacting them at 50 to 150° C. at normal pressure for about 20 minutes to 100 hours.

The objective product can be isolated by a publicly known method after the reaction terminates. The compound represented by the following formula (0) from which the repeat unit represented by the above formula (1) is derived, which is the objective product, can be obtained by, for example, concentrating the reaction liquid, precipitating the reaction product by the addition of pure water, cooling the reaction liquid to room temperature, then separating the precipitates by filtration, filtering and drying the obtained solid matter, then separating and purifying the solid matter from by-products by column chromatography, and distilling off the solvent, followed by filtration and drying.

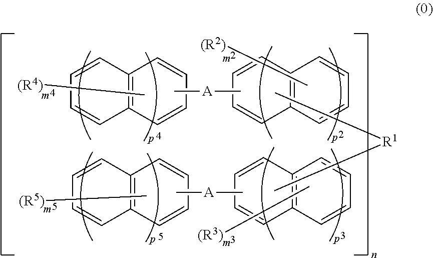

Specific examples of the resin of the present embodiment include a resin that has been made novolac obtained through, for example, a condensation reaction between the compound represented by the above formula (0) and an aldehyde or ketone, which is a crosslinking compound.

Here, examples of the aldehyde to be used upon making the compound represented by the above formula (0) novolac include, without particular limitations, formaldehyde, trioxane, paraformaldehyde, benzaldehyde, acetaldehyde, propylaldehyde, phenylacetaldehyde, phenylpropylaldehyde, hydroxybenzaldehyde, chlorobenzaldehyde, nitrobenzaldehyde, methylbenzaldehyde, ethylbenzaldehyde, butylbenzaldehyde, biphenylaldehyde, naphthaldehyde, anthracenecarbaldehyde, phenanthrenecarbaldehyde, pyrenecarbaldehyde, and furfural. These aldehydes are used alone as one kind or in combination of two or more kinds. Among them, it is preferable to use one or more selected from the group consisting of benzaldehyde, phenylacetaldehyde, phenylpropylaldehyde, hydroxybenzaldehyde, chlorobenzaldehyde, nitrobenzaldehyde, methylbenzaldehyde, ethylbenzaldehyde, butylbenzaldehyde, cyclohexylbenzaldehyde, biphenylaldehyde, naphthaldehyde, anthracenecarbaldehyde, phenanthrenecarbaldehyde, pyrenecarbaldehyde and furfural from the viewpoint that high heat resistance can be exhibited; it is preferable to use one or more selected from the group consisting of benzaldehyde, hydroxybenzaldehyde, chlorobenzaldehyde, nitrobenzaldehyde, methylbenzaldehyde, ethylbenzaldehyde, butylbenzaldehyde, cyclohexylbenzaldehyde, biphenylaldehyde, naphthaldehyde, anthracenecarbaldehyde, phenanthrenecarbaldehyde, pyrenecarbaldehyde and furfural from the viewpoint of improving etching resistance; and it is more preferable to use formaldehyde. The amount of the aldehyde used is not particularly limited, and is preferably 0.2 to 5 mol and more preferably 0.5 to 2 mol based on 1 mol of the compound represented by the above formula (0).

Examples of the ketone to be used upon making the compound represented by the above formula (0) novolac include, without particular limitations, acetone, methyl ethyl ketone, cyclobutanone, cyclopentanone, cyclohexanone, norbornanone, tricyclohexanone, tricyclodecanone, adamantanone, fluorenone, benzofluorenone, acenaphthenequinone, acenaphthenone, anthraquinone, acetophenone, diacetylbenzene, triacetylbenzene, acetonaphthone, diphenylcarbonylnaphthalene, phenylcarbonylbiphenyl, diphenylcarbonylbiphenyl, benzophenone, diphenylcarbonylbenzene, triphenylcarbonylbenzene, benzonaphthone, diphenylcarbonylnaphthalene, phenylcarbonylbiphenyl, and diphenylcarbonylbiphenyl. These ketones are used alone as one kind or in combination of two or more kinds. Among them, it is preferable to use one or more selected from the group consisting of a compound represented by the following formula (U1-0), cyclopentanone, cyclohexanone, norbornanone, tricyclohexanone, tricyclodecanone, adamantanone, fluorenone, benzofluorenone, acenaphthenequinone, acenaphthenone, anthraquinone, acetophenone, diacetylbenzene, triacetylbenzene, acetonaphthone, diphenylcarbonylnaphthalene, phenylcarbonylbiphenyl, diphenylcarbonylbiphenyl, benzophenone, diphenylcarbonylbenzene, triphenylcarbonylbenzene, benzonaphthone, diphenylcarbonylnaphthalene, phenylcarbonylbiphenyl and diphenylcarbonylbiphenyl from the viewpoint that high heat resistance can be exhibited, and it is more preferable to use one or more selected from the group consisting of a compound represented by the following formula (U1-0), acetophenone, diacetylbenzene, triacetylbenzene, acetonaphthone, diphenylcarbonylnaphthalene, phenylcarbonylbiphenyl, diphenylcarbonylbiphenyl, benzophenone, diphenylcarbonylbenzene, triphenylcarbonylbenzene, benzonaphthone, diphenylcarbonylnaphthalene, phenylcarbonylbiphenyl and diphenylcarbonylbiphenyl from the viewpoint of improving etching resistance. The amount of the ketone used is not particularly limited, and is preferably 0.2 to 5 mol and more preferably 0.5 to 2 mol based on 1 mol of the compound represented by the above formula (0).

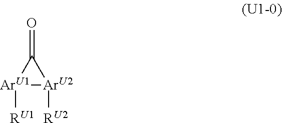

In the formula (U1-0), Ar^{U1}, Ar^{U2}, R^{U1}, and R^{U2} are as defined in the formula (U1).

A catalyst can also be used in the condensation reaction between the compound represented by the above formula (0) and the aldehyde or ketone. The acid catalyst or base catalyst to be used herein can be arbitrarily selected for use from publicly known catalysts and is not particularly limited. Examples of such an acid catalyst include, without particular limitations, an inorganic acid such as hydrochloric acid, sulfuric acid, phosphoric acid, hydrobromic acid, and hydrofluoric acid; an organic acid such as oxalic acid, malonic acid, succinic acid, adipic acid, sebacic acid, citric acid, fumaric acid, maleic acid, formic acid, p-toluenesulfonic acid, methanesulfonic acid, trifluoroacetic acid, dichloroacetic acid, trichloroacetic acid, trifluoromethanesulfonic acid, benzenesulfonic acid, naphthalenesulfonic acid, and naphthalenedisulfonic acid; a Lewis acid such as zinc chloride, aluminum chloride, iron chloride, and boron trifluoride; and a solid acid such as tungstosilicic acid, tungstophosphoric acid, silicomolybdic acid, and phosphomolybdic acid. These catalysts are used alone as one kind or in combination of two or more kinds. Among them, organic acids and solid acids are preferable from the viewpoint of production, and hydrochloric acid or sulfuric acid is preferable from the viewpoint of production such as easy availability and handleability. The amount of the acid catalyst used can be arbitrarily set according to, for example, the kind of the raw materials used and the catalyst used and moreover the reaction conditions and is not particularly limited, and is preferably 0.01 to 100 parts by mass based on 100 parts by mass of the reaction raw materials.

However, in the case of a copolymerization reaction with a compound having a non-conjugated double bond, such as indene, hydroxyindene, benzofuran, hydroxyanthracene, acenaphthylene, biphenyl, bisphenol, trisphenol, dicyclopentadiene, tetrahydroindene, 4-vinylcyclohexene, norbornadiene, 5-vinylnorborn-2-ene, α-pinene, β-pinene and limonene, the aldehyde or ketone is not necessarily needed.

A reaction solvent can also be used in the condensation reaction between the compound represented by the above formula (0) and the aldehyde or ketone. The reaction solvent in the polycondensation can be arbitrarily selected for use from publicly known solvents and is not particularly limited, and examples thereof include water, methanol, ethanol, propanol, butanol, tetrahydrofuran, dioxane, and a mixed solvent thereof. These solvents are used alone as one kind or in combination of two or more kinds.

The amount of the solvent used can be arbitrarily set according to, for example, the kind of the raw materials used and the catalyst used and moreover the reaction conditions and is not particularly limited, and is preferably in the range of 0 to 2000 parts by mass based on 100 parts by mass of the reaction raw materials. Furthermore, the reaction temperature can be arbitrarily selected according to the reactivity of the reaction raw materials and is not particularly limited, and is usually within the range of 10 to 200° C. Examples of the reaction method include a method in which the compound represented by the above formula (1), the aldehyde and/or ketone, and the catalyst are charged in a batch, or a method in which the compound represented by the above formula (0) and the aldehyde and/or ketone are dripped successively in the presence of the catalyst.

After the polycondensation reaction terminates, isolation of the obtained compound can be carried out according to a conventional method, and is not particularly limited. For example, by adopting a commonly used approach in which the temperature of the reaction vessel is elevated to 130 to 230° C. in order to remove unreacted raw materials, catalyst, etc. present in the system, and volatile portions are removed at about 1 to 50 mmHg, the objective product (for example, the resin that has been made novolac) can be obtained.

The resin of the present embodiment is also obtained upon the synthesis reaction of the compound represented by the above formula (0). This corresponds to the case where the same aldehyde or ketone is used upon polymerizing the compound represented by the above formula (0) as that used in the synthesis of the compound of the above formula (0).

Here, the resin of the present embodiment may be a homopolymer of the compound represented by the above formula (0), or may be a copolymer with a further phenol. Here, examples of the copolymerizable phenol include, without particular limitations, compounds represented by the following formula (U2-0), phenol, cresol, dimethylphenol, trimethylphenol, butylphenol, phenylphenol, diphenylphenol, naphthylphenol, resorcinol, methylresorcinol, catechol, butylcatechol, methoxyphenol, methoxyphenol, propylphenol, pyrogallol, and thymol.

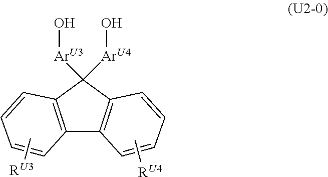

In the formula (U2-0), Ar^{U3}, Ar^{U4}, R^{U3}, and R^{U4} are as defined in the formula (U2).

In addition, the resin of the present embodiment may be a copolymer with a polymerizable monomer other than the further phenol mentioned above. Examples of the copolymerization monomer include, without particular limitations, naphthol, methylnaphthol, methoxynaphthol, dihydroxynaphthalene, indene, hydroxyindene, benzofuran, hydroxyanthracene, acenaphthylene, biphenyl, bisphenol, trisphenol, dicyclopentadiene, tetrahydroindene, 4-vinylcyclohexene, norbornadiene, vinylnorbornene, pinene, and limonene. The resin of the present embodiment may be a copolymer of two or more components (for example, a binary to quaternary system) composed of the compound represented by the above formula (0) and the above phenol, may be a copolymer of two or more components (for example, a binary to quaternary system) composed of the compound represented by the above formula (0) and the above copolymerization monomer, or may be a copolymer of three or more components (for example, a tertiary to quaternary system) composed of the compound represented by the above formula (0), the above phenol, and the above copolymerization monomer.

The weight average molecular weight (Mw) of the resin of the present embodiment is not particularly limited, and is, in terms of polystyrene through GPC measurement, preferably 500 to 30,000 and more preferably 750 to 20,000. In addition, the resin of the present embodiment preferably has dispersibility (weight average molecular weight Mw/number average molecular weight Mn) within the range of 1.2 to 7 from the viewpoint of enhancing crosslinking efficiency while suppressing volatile components during baking.

It is preferable that the resin obtained using the compound represented by the formula (0) as a monomer have high solubility in a solvent from the viewpoint of easier application to a wet process, etc. More specifically, in the case of using propylene glycol monomethyl ether (PGME) and/or propylene glycol monomethyl ether acetate (PGMEA) as a solvent, it is preferable that the compound and/or resin have a solubility of 10% by mass or more in the solvent. Here, the solubility in PGME and/or PGMEA is defined as “mass of the resin/(mass of the resin+mass of the solvent)×100 (% by mass)”. For example, 10 g of the compound represented by the above formula (0) and/or the resin obtained using the compound as a monomer is evaluated as being dissolved in 90 g of PGMEA when the solubility of the compound represented by the formula (0) and/or the resin obtained using the compound as a monomer in PGMEA is “10% by mass or more”; and 10 g of the compound and/or the resin is evaluated as being not dissolved in 90 g of PGMEA when the solubility is “less than 10% by mass”.

As an example of the resin of the present embodiment, for example, when a compound represented by the following formula (BisP-1), a compound represented by the following formula (U1-1), and a compound represented by the following formula (U2-1) are polymerized, a resin represented by the following formula (A-0a) is obtained. However, the arrangement order of each repeat unit of (A-0a) is arbitrary.

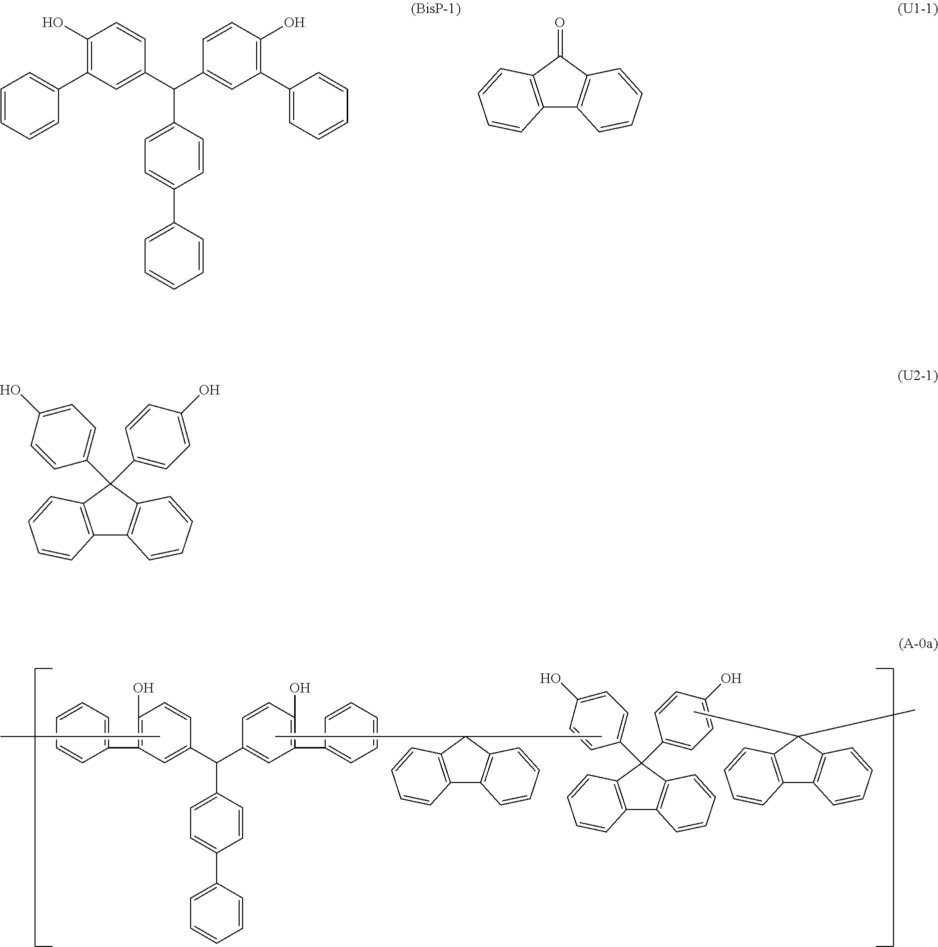

Further, for example, when a compound represented by the following formula (PRBiF-1), the compound represented by the formula (U1-1), and the compound represented by the formula (U2-1) are polymerized, a polymer represented by the following formula (A-0b) is obtained. However, the arrangement order of each repeat unit of (A-0b) is arbitrary.

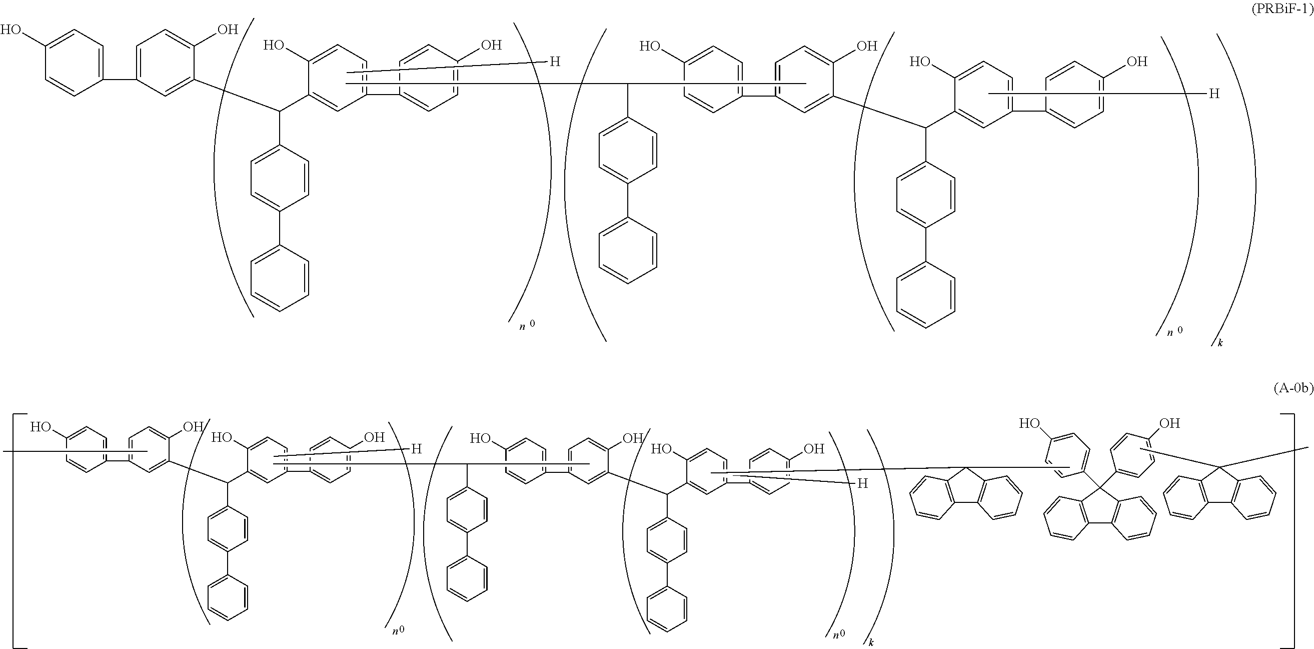

### [Composition]

The composition of the present embodiment contains a resin containing a repeat unit represented by each of the formulas described above.

The composition of the present embodiment contains the resin of the present embodiment, and is thus applicable to a wet process and is excellent in heat resistance and smoothing properties. Furthermore, the composition of the present embodiment contains the resin, and can therefore form a film for lithography that is prevented from being deteriorated upon baking at a high temperature, and is excellent in etching resistance against oxygen plasma etching or the like. Furthermore, the composition of the present embodiment is also excellent in adhesiveness to a resist layer and can therefore form an excellent resist pattern. For this reason, the composition of the present embodiment is suitably used in film formation for lithography.

In the present embodiment, the film for lithography refers to a film having a higher dry etching rate compared with that of the photoresist layer. Examples of the film for lithography include a film used for embedding and smoothening steps of layers to be processed, a resist upperlayer film, and a resist underlayer film.

The film forming material for lithography of the present embodiment may contain an organic solvent, a crosslinking agent, an acid generating agent, and a further component, in addition to the resin of the present embodiment, if required. Hereinafter, these optional components will be described.

### [Solvent]

A film forming material for lithography of the present embodiment may contain a solvent. The solvent is not particularly limited as long as it is a solvent that can dissolves the resin of the present embodiment. Here, the resin of the present embodiment has excellent solubility in an organic solvent, as mentioned above, and therefore, various organic solvents are suitably used.

Examples of the solvent include, but are not particularly limited to: a ketone-based solvent such as acetone, methyl ethyl ketone, methyl isobutyl ketone, and cyclohexanone; a cellosolve-based solvent such as propylene glycol monomethyl ether and propylene glycol monomethyl ether acetate; an ester-based solvent such as ethyl lactate, methyl acetate, ethyl acetate, butyl acetate, isoamyl acetate, ethyl lactate, methyl methoxypropionate, and methyl hydroxyisobutyrate; an alcohol-based solvent such as methanol, ethanol, isopropanol, and 1-ethoxy-2-propanol; and an aromatic hydrocarbon such as toluene, xylene, and anisole. These solvents are used alone as one kind or in combination of two or more kinds.

Among the above solvents, from the viewpoint of safety, one or more selected from the group consisting of cyclohexanone, propylene glycol monomethyl ether, propylene glycol monomethyl ether acetate, ethyl lactate, methyl hydroxyisobutyrate and anisole are preferable.

The content of the solvent is not particularly limited and is preferably 100 to 10,000 parts by mass based on 100 parts by mass of the film forming material for lithography, more preferably 200 to 5,000 parts by mass, and still more preferably 200 to 1,000 parts by mass, from the viewpoint of solubility and film formation.

### [Crosslinking Agent]

The film forming material for lithography of the present embodiment may contain a crosslinking agent from the viewpoint of, for example, suppressing intermixing. The crosslinking agent is not particularly limited, and a crosslinking agent described in, for example, International Publication No. WO 2013/024779 can be used.

Examples of the crosslinking agent include, but not particularly limited to, a phenol compound, an epoxy compound, a cyanate compound, an amino compound, a benzoxazine compound, an acrylate compound, a melamine compound, a guanamine compound, a glycoluril compound, a urea compound, an isocyanate compound, and an azide compound. Specific examples of these compounds include those described in International Publication No. WO 2020/026879 and International Publication No. WO 2019/151400. These crosslinking agents are used alone as one kind or in combination of two or more kinds. Among them, one or more selected from the group consisting of a benzoxazine compound, an epoxy compound and a cyanate compound are preferable, and a benzoxazine compound is more preferable from the viewpoint of improvement in etching resistance.

In the film forming material for lithography of the present embodiment, a crosslinking agent having at least one allyl group may be used from the viewpoint of improvement in crosslinkability. Examples of the crosslinking agent having at least one allyl group include, but not particularly limited to, those described in International Publication No. WO 2020/026879 and International Publication No. WO 2019/151400.

In the present embodiment, the content of the crosslinking agent is not particularly limited, and is preferably 0.1 to 100 parts by mass, more preferably 5 to 50 parts by mass, and still more preferably 10 to 40 parts by mass based on 100 parts by mass of the film forming material for lithography. By setting the content of the crosslinking agent to the above range, occurrence of a mixing event with a resist layer tends to be prevented. Also, an antireflection effect is enhanced, and film formability after crosslinking tends to be enhanced.

### [Crosslinking Promoting Agent]

The film forming material for lithography of the present embodiment may contain a crosslinking promoting agent for accelerating crosslinking reaction (curing reaction), if required. Examples of the crosslinking promoting agent include a radical polymerization initiator.

The radical polymerization initiator may be a photopolymerization initiator that initiates radical polymerization by light, or may be a thermal polymerization initiator that initiates radical polymerization by heat. Examples of the radical polymerization initiator include at least one selected from the group consisting of a ketone-based photopolymerization initiator, an organic peroxide-based polymerization initiator and an azo-based polymerization initiator.

Examples of such radical polymerization initiators include, but are not particularly limited to, those described in International Publication No. WO 2019/151400 and International Publication No. WO 2018/016614.

These radical polymerization initiators are used alone as one kind or in combination of two or more kinds.

### [Acid Generating Agent]

The film forming material for lithography of the present embodiment may contain an acid generating agent from the viewpoint of, for example, further accelerating crosslinking reaction by heat. An acid generating agent that generates an acid by thermal decomposition, an acid generating agent that generates an acid by light irradiation, and the like are known, any of which can be used. For example, an acid generating agent described in International Publication No. WO 2013/024779 can be used.

The content of the acid generating agent in the film forming material for lithography is not particularly limited and is preferably 0.1 to 50 parts by mass, and more preferably 0.5 to 40 parts by mass, based on 100 parts by mass of the film forming material for lithography. By setting the content of the acid generating agent to the above range, crosslinking reaction tends to be enhanced and occurrence of a mixing event with a resist layer tends to be prevented.

### [Basic Compound]

The film forming material for lithography of the present embodiment may also contain a basic compound from the viewpoint of, for example, improving storage stability.

The basic compound plays a role to prevent crosslinking reaction from proceeding due to a trace amount of an acid generated from the acid generating agent, that is, a role as a quencher against the acid. Examples of such a basic compound include, but are not particularly limited to, those described in International Publication No. WO 2013/024779.

The content of the basic compound in the film forming material for lithography of the present embodiment is not particularly limited, and is preferably 0.001 to 2 parts by mass, and more preferably 0.01 to 1 part by mass based on 100 parts by mass of the film forming material for lithography. By setting the content of the basic compound to the above range, storage stability tends to be enhanced without excessively deteriorating crosslinking reaction.

### [Further Additive Agent]

The underlayer film forming material of the present embodiment may also contain an additional resin and/or compound for the purpose of conferring thermosetting or light curing properties or controlling absorbance. Examples of such an additional resin and/or compound include, without particular limitations, a naphthol resin, a xylene resin naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin containing no aromatic ring; and a resin or compound containing an alicyclic structure, such as a rosin-based resin, a cyclodextrin, an adamantine(poly)ol, a tricyclodecane(poly)ol, and a derivative thereof. The film forming material for lithography of the present embodiment may also contain a publicly known additive agent. Examples of the publicly known additive agent include, but are not limited to, a thermal and/or light curing catalyst, a polymerization inhibitor, a flame retardant, a filler, a coupling agent, a thermosetting resin, a light curable resin, a dye, a pigment, a thickener, a lubricant, an antifoaming agent, a leveling agent, an ultraviolet absorber, a surfactant, a colorant, and a nonionic surfactant.

### [Underlayer Film for Lithography]

The underlayer film for lithography of the present embodiment is formed from the film forming material for lithography of the present embodiment.

### [Resist Pattern Formation Method]

The resist pattern formation method of the present embodiment comprises: an underlayer film formation step of forming an underlayer film on a substrate using the composition of the present embodiment; a photoresist layer formation step of forming at least one photoresist layer on the underlayer film formed through the underlayer film formation step; and a step of irradiating a predetermined region of the photoresist layer formed through the photoresist layer formation step with radiation for development. The resist pattern formation method of the present embodiment can be used for forming various patterns, and is preferably a method for forming an insulating film pattern.

### [Circuit Pattern Formation Method]

The circuit pattern formation method of the present embodiment comprises: an underlayer film formation step of forming an underlayer film on a substrate using the composition of the present embodiment; an intermediate layer film formation step of forming an intermediate layer film on the underlayer film formed through the underlayer film formation step; a photoresist layer formation step of forming at least one photoresist layer on the intermediate layer film formed through the intermediate layer film formation step; a resist pattern formation step of irradiating a predetermined region of the photoresist layer formed through the photoresist layer formation step with radiation for development, thereby forming a resist pattern; an intermediate layer film pattern formation step of etching the intermediate layer film with the resist pattern formed through the resist pattern formation step as a mask, thereby forming an intermediate layer film pattern; an underlayer film pattern formation step of etching the underlayer film with the intermediate layer film pattern formed through the intermediate layer film pattern formation step as a mask, thereby forming an underlayer film pattern; and a substrate pattern formation step of etching the substrate with the underlayer film pattern formed through the underlayer film pattern formation step as a mask, thereby forming a pattern on the substrate.

The underlayer film for lithography of the present embodiment is formed from the film forming material for lithography of the present embodiment. The formation method is not particularly limited and a publicly known method can be applied. The underlayer film can be formed by, for example, applying the film forming material for lithography of the present embodiment onto a substrate by a publicly known coating method or printing method such as spin coating or screen printing, and then removing an organic solvent by volatilization or the like.

It is preferable to perform baking in the formation of the underlayer film, for preventing occurrence of a mixing event with a resist upper layer film while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be arbitrarily selected according to required performance and is not particularly limited, but is preferably 30 to 20,000 nm, and more preferably 50 to 15,000 nm.

After preparing the underlayer film, it is preferable to prepare a silicon-containing resist layer or a single-layer resist made of hydrocarbon on the underlayer film in the case of a two-layer process, and to prepare a silicon-containing intermediate layer on the underlayer film and further prepare a silicon-free single-layer resist layer on the silicon-containing intermediate layer in the case of a three-layer process. In this case, a publicly known photoresist material can be used for forming this resist layer.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist generally used can be used.

The underlayer film according to the present embodiment can also be used as an antireflection film for usual single-layer resists or an underlying material for suppression of pattern collapse. The underlayer film is excellent in etching resistance for an underlying process and can be expected to also function as a hard mask for an underlying process.

In the case of forming a resist layer from the above photoresist material, a wet process such as spin coating or screen printing is preferably used, as in the case of forming the above underlayer film. After coating with the resist material by spin coating or the like, prebaking is generally performed. This prebaking is preferably performed at 80 to 180° C. in the range of 10 to 300 seconds. Thereafter, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be arbitrarily selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the above two-layer process is applicable. Particularly, it is preferable to process the intermediate layer in a three-layer process by using chlorofluorocarbon-based gas and using the resist pattern as a mask. Thereafter, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, ALD, or the like. A method for forming the nitride film is not limited, and, for example, a method described in Japanese Patent Laid-Open No. 2002-334869 (Patent Literature 6) or International Publication No. WO2004/066377 (Patent Literature 7) can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is suitably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Laid-Open No. 2007-226170 (Patent Literature 8) or Japanese Patent Laid-Open No. 2007-226204 (Patent Literature 9) can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film of the present embodiment is that it is excellent in etching resistance of the substrates. The substrate can be arbitrarily selected for use from publicly known ones and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is generally used. The thickness of the substrate to be processed or the film to be processed is not particularly limited and is generally preferably about 50 to 1,000,000 nm, and more preferably 75 to 50,000 nm.

The composition of the present embodiment can be prepared by adding each of the above components and mixing them using a stirrer or the like. When the composition of the present embodiment contains a filler or a pigment, it can be prepared by dispersion or mixing using a dispersion apparatus such as a dissolver, a homogenizer, and a three-roll mill.

### [Purification Method of Resin]

The method for purifying the resin of the present embodiment comprises: an extraction step of bringing a solution containing the resin of the present embodiment and an organic solvent that does not inadvertently mix with water into contact with an acidic aqueous solution, thereby carrying out extraction. More specifically, in the purification method of the present embodiment, the resin of the present embodiment is dissolved in an organic solvent that does not inadvertently mix with water; the resultant solution is brought into contact with an acidic aqueous solution to carry out an extraction treatment, thereby transferring metals contained in the solution (A) containing the resin of the present embodiment and the organic solvent to the aqueous phase; and then the organic phase and the aqueous phase are separated and purified. Through the purification method of the present embodiment, the content of various metals in the resin of the present embodiment can be significantly reduced.

In the present embodiment, the “organic solvent that does not inadvertently mix with water” means that the solubility is less than 50% by mass in water at 20 to 90° C., and preferably less than 25% by mass from the viewpoint of productivity. The organic solvent that does not inadvertently mix with water is not particularly limited, and is preferably an organic solvent that is safely applicable to semiconductor manufacturing processes. Normally, the amount of the organic solvent used is approximately 1 to 100 times by weight relative to the resin of the present embodiment.

Specific examples of the solvent to be used include those described in International Publication No. WO 2015/080240. These solvents are used alone as one kind or in combination of two or more kinds. Among them, toluene, 2-heptanone, cyclohexanone, cyclopentanone, methyl isobutyl ketone, propylene glycol monomethyl ether acetate, ethyl acetate, and the like are preferable, and cyclohexanone and propylene glycol monomethyl ether acetate are particularly preferable.

The acidic aqueous solution to be used is appropriately selected from aqueous solutions in which generally known organic or inorganic compounds are dissolved in water. Examples thereof include those described in International Publication No. WO 2015/080240. These acidic aqueous solutions are used alone as one kind or in combination of two or more kinds. Among them, an aqueous solution of sulfuric acid, nitric acid, and a carboxylic acid such as acetic acid, oxalic acid, tartaric acid and citric acid are preferable; an aqueous solution of sulfuric acid, oxalic acid, tartaric acid and citric acid are still more preferable; and an aqueous solution of oxalic acid is particularly preferable. It is considered that a polyvalent carboxylic acid such as oxalic acid, tartaric acid, and citric acid coordinates with metal ions and provides a chelating effect, and thus is capable of removing more metals. In addition, as the water used herein, water, the metal content of which is small, such as ion exchanged water, is suitably used according to the purpose of the present invention.

The pH of the acidic aqueous solution to be used in the present embodiment is not particularly limited; however, when the acidity of the aqueous solution is too high, it may have a negative influence on the resin, which is not preferable. Normally, the pH range is about 0 to 5, and is more preferably about pH 0 to 3.

The amount of the acidic aqueous solution to be used in the present embodiment is not particularly limited; however, when the amount is too small, it is required to increase the number of extraction treatments for removing metals, and on the other hand, when the amount of the aqueous solution is too large, the entire fluid volume becomes large, which may cause operational problems. The amount of the aqueous solution used is usually 10 to 200% by mass, and preferably 20 to 100% by mass, based on the solution of the resin of the present embodiment dissolved in an organic solvent.

In the present embodiment, for example, by bringing the acidic aqueous solution as described above into contact with the solution (A) containing the resin of the present embodiment and the organic solvent that does not inadvertently mix with water, metals are extracted.

The temperature when extraction treatment is carried out is generally in the range of 20 to 90° C., and preferably 30 to 80° C. The extraction operation is carried out, for example, by thoroughly mixing the solution (A) and the acidic aqueous solution by stirring or the like and then leaving the obtained mixed solution to stand still. Thereby, metals contained in the solution containing the resin of the present embodiment and the organic solvent are transferred to the aqueous phase. Also, by this operation, the acidity of the solution is lowered, and the degradation of the resin of the present embodiment can be suppressed.

The obtained mixture is separated into an aqueous phase and a solution phase containing the resin of the present embodiment and the organic solvent, and thus the solution containing the resin of the present embodiment and the organic solvent is recovered by decantation or the like. The time for leaving the mixed solution to stand still is not particularly limited; however, when the time for leaving the mixed solution to stand still is too short, separation of the solution phase containing the organic solvent and the aqueous phase becomes poor, which is not preferable. Normally, the time for leaving the mixed solution to stand still is 1 minute or longer, more preferably 10 minutes or longer, and still more preferably 30 minutes or longer. While the extraction treatment may be carried out only once, it is also effective to repeat mixing, leaving-to-stand-still, and separating operations multiple times.

When such an extraction treatment is carried out using the acidic aqueous solution, after the treatment, it is preferable to further subject the recovered solution (A), which has been extracted from the aqueous solution and contains the resin of the present embodiment and the organic solvent, to an extraction treatment with water. The extraction operation is carried out by thoroughly mixing the solution (A) and the acidic aqueous solution by stirring or the like and then leaving the obtained mixed solution to stand still. Then, the obtained solution is separated into an aqueous phase and a solution phase containing the resin of the present embodiment and the organic solvent, and thus the solution phase containing the resin of the present embodiment and the organic solvent is recovered by decantation or the like. In addition, as the water used herein, water, the metal content of which is small, such as ion exchanged water, is preferable according to the purpose of the present invention. While the extraction treatment may be performed once, it is effective to repeat mixing, leaving-to-stand-still, and separating operations multiple times. The proportions of both used in the extraction treatment and the temperature, time, and other conditions are not particularly limited, and may be the same as those of the previous contact treatment with the acidic aqueous solution.

Water that is present in the thus-obtained solution containing the resin of the present embodiment and the organic solvent can be easily removed by performing vacuum distillation or a like operation. Also, if required, the concentration of the resin of the present embodiment can be regulated to be any concentration by adding an organic solvent.

For the method for obtaining the resin of the present embodiment alone from the obtained solution containing the resin of the present embodiment and the organic solvent, a publicly known method can be carried out, such as reduced-pressure removal, separation by reprecipitation, and a combination thereof. Publicly known treatments such as concentration operation, filtration operation, centrifugation operation, and drying operation can be performed if required.

### EXAMPLES

The present embodiment will be described in more detail with reference to synthesis examples and examples below. However, the present embodiment is not limited to these examples by any means.

### (Molecular Weight)

The molecular weight of the compound or the resin was measured through LC-MS analysis by using a product manufactured by Waters Corp., “Acquity UPLC/MALDI-Synapt HDMS”.

### (Evaluation of Solubility)

At 23° C., the compound or the resin was dissolved in propylene glycol monomethyl ether (PGME) to form a 5 mass % solution. Thereafter, the solubility after leaving the solution to stand still at 5° C. for 30 days was evaluated according to the following criteria.

Evaluation A: no precipitate was visually confirmed

Evaluation C: precipitates were visually confirmed

### (Synthesis Example 1) Synthesis of BiF-1

A container (internal capacity: 200 mL) equipped with a stirrer, a condenser tube, and a burette was prepared. To this container, 30 g (161 mmol) of 4,4-biphenol (a reagent manufactured by Tokyo Chemical Industry Co., Ltd.), 15 g (82 mmol) of 4-biphenylaldehyde (manufactured by Mitsubishi Gas Chemical Company, Inc.), and 100 mL of butyl acetate were charged, and 3.9 g (21 mmol) of p-toluenesulfonic acid (a reagent manufactured by Kanto Chemical Co., Inc.) was added to prepare a reaction liquid. This reaction liquid was stirred at 90° C. for 3 hours and reacted. Next, the reaction liquid was concentrated. The reaction product was precipitated by the addition of 50 g of heptane. After cooling to room temperature, the precipitates were separated by filtration. The solid matter obtained by filtration was dried and then separated and purified by column chromatography to obtain 5.8 g of an objective compound represented by the following formula (BiF-1).

The following peaks were found by 400 MHz-¹H-NMR, and the compound was confirmed to have a chemical structure of the following formula.

¹H-NMR: (d-DMSO, Internal standard TMS)

δ (ppm) 9.4 (4H, O—H), 6.8-7.8 (22H, Ph-H), 6.2 (1H, C—H)

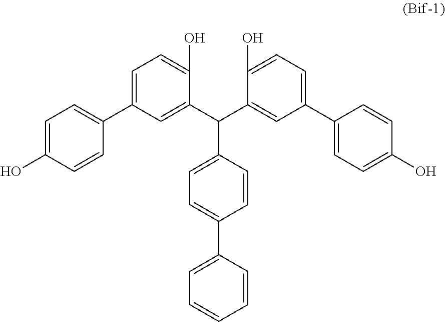 [SMILES: Oc1ccc(-c2ccc(O)c(C(c3ccc(-c4ccccc4)cc3)c3cc(-c4ccc(O)cc4)ccc3O)c2)cc1]

### (Synthesis Example 2) Synthesis of TeF-1

A container (internal capacity: 500 mL) equipped with a stirrer, a condenser tube, and a burette was prepared. To this container, 30 g (161 mmol) of 4,4-biphenol (a reagent manufactured by Tokyo Chemical Industry Co., Ltd.), 5.4 g (40 mmol) of terephthalaldehyde (a reagent manufactured by Tokyo Chemical Industry Co., Ltd.), and 300 g of ethyl glyme (a special grade reagent manufactured by Tokyo Chemical Industry Co., Ltd.) were charged, and 3.9 g (21 mmol) of p-toluenesulfonic acid (a reagent manufactured by Kanto Chemical Co., Inc.) was added to prepare a reaction liquid. This reaction liquid was stirred at 90° C. for 3 hours and reacted. Next, the reaction liquid was concentrated. The reaction product was precipitated by the addition of 50 g of heptane. After cooling to room temperature, the precipitates were separated by filtration. The solid matter obtained by filtration was dried and then separated and purified by column chromatography to obtain 3.2 g of an objective compound (TeF-1) represented by the following formula.

The following peaks were found by 400 MHz-¹H-NMR, and the compound was confirmed to have a chemical structure of the following formula.

¹H-NMR: (d-DMSO, Internal standard TMS)

δ (ppm) 9.4 (8H, O—H), 6.8-7.8 (32H, Ph-H), 6.2 (2H, C—H)

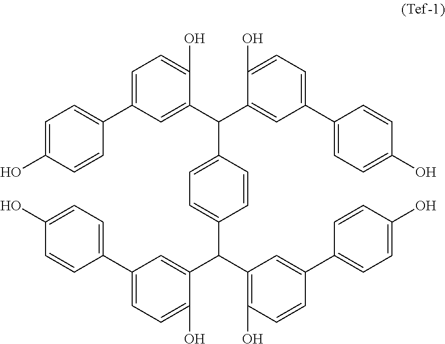 [SMILES: Oc1ccc(-c2ccc(O)c(C(c3ccc(C(c4cc(-c5ccc(O)cc5)ccc4O)c4cc(-c5ccc(O)cc5)ccc4O)cc3)c3cc(-c4ccc(O)cc4)ccc3O)c2)cc1]

### (Synthesis Example 3) Synthesis of PBiF-1

A reaction was performed in the same manner as in Synthesis Example 1 except that BiF-1 obtained in Synthesis Example 1 was used instead of 4,4′-biphenol to obtain 30 g of an objective resin (PBiF-1) represented by the following formula (PBiF-1).

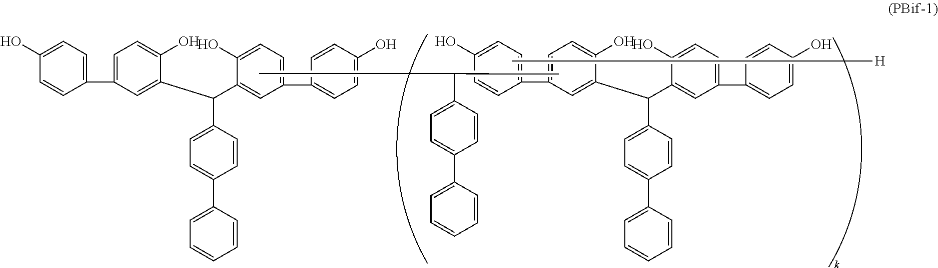

### (Synthesis Example 4) Synthesis of RBiF-1

A container (internal capacity: 200 mL) equipped with a stirrer, a condenser tube, and a burette was prepared. To this container, 30 g (161 mmol) of 4,4-biphenol (a reagent manufactured by Tokyo Chemical Industry Co., Ltd.), 15 g (82 mmol) of 4-biphenylaldehyde (manufactured by Mitsubishi Gas Chemical Company, Inc.), and 100 mL of butyl acetate were charged, and 3.9 g (21 mmol) of p-toluenesulfonic acid (a reagent manufactured by Kanto Chemical Co., Inc.) was added to prepare a reaction liquid. This reaction liquid was stirred at 90° C. for 3 hours and reacted. Next, the reaction liquid was concentrated. The reaction product was precipitated by the addition of 50 g of heptane. After cooling to room temperature, the precipitates were separated by filtration. The solid matter obtained by filtration was dried to obtain 21 g of an objective compound represented by the following formula (RBiF-1).

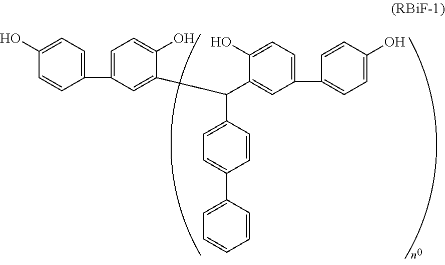

### (Synthesis Example 5) Synthesis of BisP-1

To a container (internal capacity: 500 mL) equipped with a stirrer, a condenser tube, and a burette, 34.0 g (200 mmol) of o-phenylphenol (reagent manufactured by Sigma-Aldrich), 18.2 g (100 mmol) of 4-biphenylaldehyde (manufactured by Mitsubishi Gas Chemical Co., Inc.), and 200 mL of 1,4-dioxane were charged, and 10 mL of 95% sulfuric acid was added. The reaction solution was stirred at 100° C. for 6 hours and reacted. Next, the reaction liquid was neutralized with 24% aqueous sodium hydroxide solution. The reaction product was precipitated by the addition of 100 g of pure water. After cooling to room temperature, the precipitates were separated by filtration. The solid matter obtained was dried and then separated and purified by column chromatography to obtain 25.5 g of an objective compound (BisP-1) represented by the following formula.

The following peaks were found by 400 MHz-¹H-NMR, and the compound was confirmed to have a chemical structure of the following formula.

¹H-NMR: (d-DMSO, internal standard TMS)

δ (ppm) 9.1 (2H, O—H), 7.2-8.5 (25H, Ph-H), 5.6 (1H, C—H)

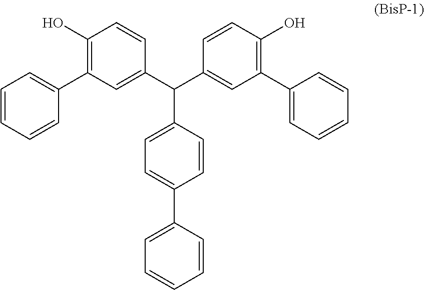 [SMILES: Oc1ccc(C(c2ccc(-c3ccccc3)cc2)c2ccc(O)c(-c3ccccc3)c2)cc1-c1ccccc1]

### (Synthesis Examples 6 to 9) Synthesis of BisP-2 to BisP-5

Objective compounds (BisP-2), (BisP-3), (BisP-4), and (BisP-5) represented by the following formulas were obtained in the same manner as in Synthesis Example 5 except that benzaldehyde, p-methylbenzaldehyde, 1-naphthaldehyde, and 2-naphthaldehyde was used instead of 4-biphenylaldehyde, respectively.

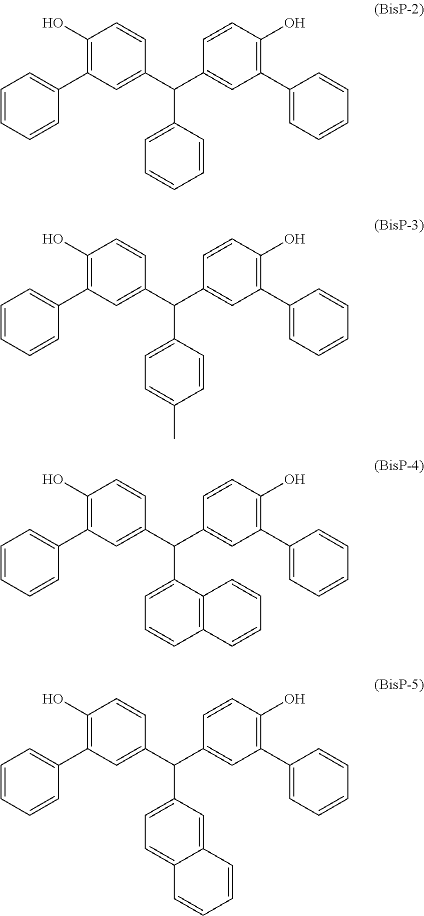 [SMILES: Oc1ccc(C(c2ccccc2)c2ccc(O)c(-c3ccccc3)c2)cc1-c1ccccc1 ; Cc1ccc(C(c2ccc(O)c(-c3ccccc3)c2)c2ccc(O)c(-c3ccccc3)c2)cc1 ; Oc1ccc(C(c2ccc(O)c(-c3ccccc3)c2)c2cccc3ccccc23)cc1-c1ccccc1 ; Oc1ccc(C(c2ccc(O)c(-c3ccccc3)c2)c2ccc3ccccc3c2)cc1-c1ccccc1]

### (Synthesis Example 10) Synthesis of BisP-6

An objective compound (BisP-6) represented by the following formula was obtained in the same manner as in Synthesis Example 5 except that 4-phenylphenol (a reagent manufactured by Kanto Chemical Co., Inc.) was used instead of o-phenylphenol (a reagent manufactured by Sigma-Aldrich).

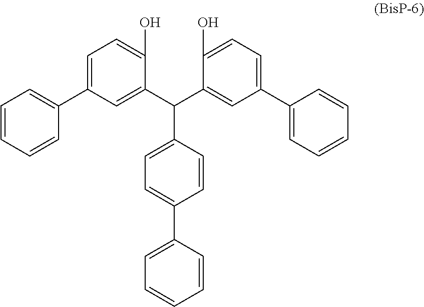 [SMILES: Oc1ccc(-c2ccccc2)cc1C(c1ccc(-c2ccccc2)cc1)c1cc(-c2ccccc2)ccc1O]

### (Synthesis Comparative Example 1)

A four necked flask (internal capacity: 10 L) equipped with a Dimroth condenser tube, a thermometer, and a stirring blade and having a detachable bottom was prepared. To this four necked flask, 1.09 kg (7 mol) of 1,5-dimethylnaphthalene (manufactured by Mitsubishi Gas Chemical Company, Inc.), 2.1 kg (28 mol as formaldehyde) of a 40 mass % aqueous formalin solution (manufactured by Mitsubishi Gas Chemical Company, Inc.), and 0.97 mL of a 98 mass % sulfuric acid (manufactured by Kanto Chemical Co., Inc.) were charged in a nitrogen stream, and the mixture was reacted for 7 hours while refluxed at 100° C. at normal pressure. Thereafter, 1.8 kg of ethylbenzene (special grade reagent manufactured by Wako Pure Chemical Industries, Ltd.) was added as a diluting solvent to the reaction liquid, and the mixture was left to stand still, followed by removal of an aqueous phase as a lower phase. Neutralization and washing with water were further performed, and ethylbenzene and unreacted 1,5-dimethylnaphthalene were distilled off under reduced pressure to obtain 1.25 kg of a dimethylnaphthalene formaldehyde resin as a light brown solid. The molecular weight of the obtained dimethylnaphthalene formaldehyde was Mn: 562.

Subsequently, a four necked flask (internal capacity: 0.5 L) equipped with a Dimroth condenser tube, a thermometer, and a stirring blade was prepared. To this four necked flask, 100 g (0.51 mol) of the dimethylnaphthalene formaldehyde resin obtained as described above, and 0.05 g of p-toluenesulfonic acid were charged in a nitrogen stream, and the temperature was raised to 190° C. at which the mixture was then heated for 2 hours, followed by stirring. Thereafter, 52.0 g (0.36 mol) of 1-naphthol was further added thereto, the temperature was further elevated to 220° C., and the mixture was reacted for 2 hours. After dilution with a solvent, neutralization and washing with water were performed, and the solvent was distilled off under reduced pressure to obtain 126.1 g of a modified resin (CR-1) as a black-brown solid.

The obtained resin (CR-1) had Mn: 885, Mw: 2220, and Mw/Mn: 4.17. Note that the Mn, Mw and Mw/Mn of the resin (CR-1) were determined by gel permeation chromatography (GPC) analysis under the following measurement conditions in terms of polystyrene.

Apparatus: Shodex GPC-101 model (a product manufactured by Showa Denko K.K.)

Column: KF-80M×3

Eluent: 1 mL/min THF

Temperature: 40° C.

### (Synthesis Working Example 1)

A container (internal capacity: 500 mL) equipped with a stirrer, a condenser tube, and a burette was prepared. To this container, 10.7 g (20 mmol) of BiF-1 obtained in Synthesis Example 1, 9.0 g (50 mmol) of 9-fluorenone (a reagent manufactured by Tokyo Chemical Industry Co., Ltd.), and 7.0 g (20 mmol) of 9,9-bis (4-hydroxyphenyl)fluorenone (a reagent manufactured by Tokyo Chemical Industry Co., Ltd.), and 150 g of ethyl glyme (a special grade reagent manufactured by Tokyo Chemical Industry Co., Ltd.) were charged, and 1.3 g (7 mmol) of p-toluenesulfonic acid (a reagent manufactured by Kanto Chemical Co., Inc.) was added to prepare a reaction liquid. This reaction liquid was stirred at 90° C. for 3 hours and reacted. Next, the reaction liquid was concentrated. The reaction product was precipitated by the addition of 50 g of heptane. After cooling to room temperature, the precipitates were separated by filtration. The solid matter obtained by filtration was dried to obtain a resin (A-1).

### (Synthesis Working Example 2)

A resin (A-2) was obtained by reacting in the same manner as in Synthesis Working Example 1 except that 16.8 g (20 mmol) of TeF-1 obtained in Synthesis Example 2 was used instead of 10.7 g (20 mmol) of BiF-1.

### (Synthesis Working Example 3)

A resin (A-3) was obtained by reacting in the same manner as in Synthesis Working Example 1 except that 10 g of PBiF-1 obtained in Synthesis Example 3 was used instead of 10.7 g (20 mmol) of BiF-1.

### (Synthesis Working Example 4)

A resin (A-4) was obtained by reacting in the same manner as in Synthesis Working Example 1 except that 10 g of RBiF-1 obtained in Synthesis Example 4 was used instead of 10.7 g (20 mmol) of BiF-1.

### (Synthesis Working Example 5)

A resin (A-5) was obtained by reacting in the same manner as in Synthesis Working Example 1 except that 10.1 g (20 mmol) of BisP-1 obtained in Synthesis Example 5 was used instead of 10.7 g (20 mmol) of BiF-1.

### (Synthesis Working Example 6)

A resin (A-6) was obtained by reacting in the same manner as in Synthesis Working Example 1 except that 8.6 g (20 mmol) of BisP-2 obtained in Synthesis Example 6 was used instead of 10.7 g (20 mmol) of BiF-1.

### (Synthesis Working Example 7)

A resin (A-7) was obtained by reacting in the same manner as in Synthesis Working Example 1 except that 8.8 g (20 mmol) of BisP-3 obtained in Synthesis Example 7 was used instead of 10.7 g (20 mmol) of BiF-1.

### (Synthesis Working Example 8)

A resin (A-8) was obtained by reacting in the same manner as in Synthesis Working Example 1 except that 9.5 g (20 mmol) of BisP-4 obtained in Synthesis Example 8 was used instead of 10.7 g (20 mmol) of BiF-1.

### (Synthesis Working Example 9)

A resin (A-9) was obtained by reacting in the same manner as in Synthesis Working Example 1 except that 9.5 g (20 mmol) of BisP-5 obtained in Synthesis Example 9 was used instead of 10.7 g (20 mmol) of BiF-1.

### (Synthesis Working Example 10)

A resin (A-10) was obtained by reacting in the same manner as in Synthesis Working Example 1 except that 10.1 g (20 mmol) of BisP-6 obtained in Synthesis Example 10 was used instead of 10.7 g (20 mmol) of BiF-1.

### (Synthesis Working Example 11)

A resin (A-11) was obtained by reacting in the same manner as in Synthesis Working Example 1 except that 5.05 g (10 mmol) of BisP-1 obtained in Synthesis Example 5 was used instead of 10.7 g (20 mmol) of BiF-1 and 10.5 g (30 mmol) of 9,9-bis (4-hydroxyphenyl)fluorenone (a reagent manufactured by Tokyo Chemical Industry Co., Ltd.) was used instead of 7.0 g (20 mmol) of 9,9-bis(4-hydroxyphenyl)fluorenone (a reagent manufactured by Tokyo Chemical Industry Co., Ltd.).

### (Synthesis Working Example 12)

A resin (A-12) was obtained by reacting in the same manner as in Synthesis Working Example 1 except that 15.1 g (30 mmol) of BisP-1 obtained in Synthesis Example 5 was used instead of 10.7 g (20 mmol) of BiF-1 and 3.50 g (10 mmol) of 9,9-bis (4-hydroxyphenyl)fluorenone (a reagent manufactured by Tokyo Chemical Industry Co., Ltd.) was used instead of 7.0 g (20 mmol) of 9,9-bis(4-hydroxyphenyl)fluorenone (a reagent manufactured by Tokyo Chemical Industry Co., Ltd.).

### Examples 1A to 18A and 21A to 29A and Comparative Example 1

Solubility test was conducted for the above resins A-1 to A-12 and CR-1. The results are shown in Table 1. Also, underlayer film forming materials for lithography (underlayer film forming compositions for lithography) were each prepared according to the compositions shown in Table 1. Next, a silicon substrate was spin coated with each of these underlayer film forming materials for lithography, and then baked at 240° C. for 60 seconds and further at 400° C. for 120 seconds to prepare each underlayer film with a film thickness of 200 nm. The following acid generating agent, crosslinking agent, and organic solvent were used.

Acid generating agent: a product manufactured by Midori Kagaku Co., Ltd., “di-tertiary butyl diphenyliodonium nonafluoromethanesulfonate” (in the tables, referred to as “DTDPI”) or a product manufactured by Kanto Chemical Co., Inc., “pyridinium p-toluenesulfonate” (in the tables, referred to as “PPTS”). Crosslinking agent: a product manufactured by Sanwa Chemical Co., Ltd., “NIKALAC MX270” (in the tables, referred to as “NIKALAC”) or a product manufactured by Honshu Chemical Industry Co., Ltd., “TMOM-BP” (compound name: 3,3′,5,5′-tetrakis(methoxymethyl)-[1,1′-biphenyl]-4,4′-diol, in the tables, referred to as “TMOM-BP”) Organic solvent: propylene glycol monomethyl ether acetate (in the tables, referred to as “PGMEA”) or a mixture of propylene glycol monomethyl ether acetate and propylene glycol monomethyl ether in a ratio of 1:1 (mass ratio) (in the tables, referred to as “PGMEA/PGME” in the tables).

For each of the obtained underlayer films, etching test was carried out under the following conditions to evaluate etching resistance. The evaluation results are shown in Table 1.

### [Etching Test]

Etching apparatus: a product manufactured by Samco International, Inc., “RIE-10NR”

Output: 50 W

Pressure: 20 Pa

Time: 2 min

Etching gas

Ar gas flow rate:CF₄ gas flow rate:O₂ gas flow rate=50:5:5 (sccm)

### [Evaluation of Etching Resistance]

The evaluation of etching resistance was carried out by the following procedures.

First, an underlayer film containing a phenol novolac resin was prepared under the same conditions as in Example 1A except that a phenol novolac resin (PSM4357 manufactured by Gunei Chemical Industry Co., Ltd.) was used instead of the resin (A-1) used in Example 1A. Then, the above etching test was carried out for this underlayer film containing a phenol novolac resin, and the etching rate (etching speed) was measured. Next, for each of the underlayer films of Examples and Comparative Example, the above etching test was carried out, and the etching rate was measured. Then, the etching resistance for each of Examples and Comparative Example was evaluated according to the following evaluation criteria on the basis of the etching rate of the underlayer film containing a phenol novolac resin.

### [Evaluation Criteria]

S: The etching rate was less than −14% as compared with the underlayer film of novolac.

A: The etching rate was −14% to −10% as compared with the underlayer film of novolac.

B: The etching rate was −10% to +5% as compared with the underlayer film of novolac.

C: The etching rate was more than +5% as compared with the underlayer film of novolac.

TABLE 1

| | | | | Crosslinking | | |
|---|---|---|---|---|---|---|
| | Resin | | Acid generating | agent | | Evaluation of |
| | (parts by | Solvent | agent | (parts by | Evaluation of | etching |
| | mass) | (parts by mass) | (parts by mass) | mass) | solubility | resistance |
| Example 1A | A-1 | PGMEA | None | None | A | A |
| | (10) | (90) | | | | |
| Example 2A | A-1 | PGMEA | DTDPI | NIKALAC | A | A |
| | (10) | (90) | (0.5) | (0.5) | | |
| Example 3A | A-2 | PGMEA | None | None | A | A |
| | (10) | (90) | | | | |
| Example 4A | A-2 | PGMEA | DTDPI | NIKALAC | A | A |
| | (10) | (90) | (0.5) | (0.5) | | |
| Example 5A | A-3 | PGMEA | DTDPI | NIKALAC | A | A |
| | (10) | (90) | (0.5) | (0.5) | | |
| Example 6A | A-4 | PGMEA | DTDPI | NIKALAC | A | A |
| | (10) | (90) | (0.5) | (0.5) | | |
| Example 7A | A-5 | PGMEA | None | None | A | S |
| | (10) | (90) | | | | |
| Example 8A | A-5 | PGMEA | DTDPI | NIKALAC | A | S |
| | (10) | (90) | (0.5) | (0.5) | | |
| Example 9A | A-6 | PGMEA | None | None | A | S |
| | (10) | (90) | | | | |
| Example 10A | A-6 | PGMEA | DTDPI | NIKALAC | A | S |
| | (10) | (90) | (0.5) | (0.5) | | |
| Example 11A | A-7 | PGMEA | None | None | A | S |
| | (10) | (90) | | | | |
| Example 12A | A-7 | PGMEA | DTDPI | NIKALAC | A | S |
| | (10) | (90) | (0.5) | (0.5) | | |
| Example 13A | A-8 | PGMEA | None | None | A | S |
| | (10) | (90) | | | | |
| Example 14A | A-8 | PGMEA | DTDPI | NIKALAC | A | S |
| | (10) | (90) | (0.5) | (0.5) | | |
| Example 15A | A-9 | PGMEA | None | None | A | S |
| | (10) | (90) | | | | |
| Example 16A | A-9 | PGMEA | DTDPI | NIKALAC | A | S |
| | (10) | (90) | (0.5) | (0.5) | | |
| Example 17A | A-10 | PGMEA | None | None | A | S |
| | (10) | (90) | | | | |
| Example 18A | A-10 | PGMEA | DTDPI | NIKALAC | A | S |
| | (10) | (90) | (0.5) | (0.5) | | |
| Example 21A | A-5 | PGMEA/PGME | DTDPI | NIKALAC | A | S |
| | (10) | (90) | (0.5) | (0.5) | | |
| Example 22A | A-5 | PGMEA | DTDPI | TMOM-BP | A | S |
| | (10) | (90) | (0.5) | (0.5) | | |
| Example 23A | A-5 | PGMEA | PPTS | NIKALAC | A | S |
| | (10) | (90) | (0.5) | (0.5) | | |
| Example 24A | A-5 | PGMEA | PPTS | TMOM-BP | A | S |
| | (10) | (90) | (0.5) | (0.5) | | |
| Example 25A | A-5 | PGMEA | PPTS | TMOM-BP | A | S |
| | (15) | (90) | (2.0) | (5.0) | | |
| Example 26A | A-11 | PGMEA | None | None | A | S |
| | (10) | (90) | | | | |
| Example 27A | A-11 | PGMEA | DTDPI | NIKALAC | A | S |
| | (10) | (90) | (0.5) | (0.5) | | |
| Example 28A | A-12 | PGMEA | None | None | A | S |
| | (10) | (90) | | | | |
| Example 29A | A-12 | PGMEA | DTDPI | NIKALAC | A | S |
| | (10) | (90) | (0.5) | (0.5) | | |
| Comparative | CR-1 | PGMEA | DTDPI | NIKALAC | A | C |
| Example 1 | (10) | (90) | (0.5) | (0.5) | | |

### Examples 1B to 18B and 21B to 29B

A SiO₂ substrate with a film thickness of 300 nm was coated with the solution of the underlayer film forming material for lithography prepared in each of the above Examples 1A to 18A and 21A to 29A, and baked at 240° C. for 60 seconds and further at 400° C. for 120 seconds to form each underlayer film with a film thickness of 70 nm. This underlayer film was coated with a resist solution for ArF and baked at 130° C. for 60 seconds to form a photoresist layer having a film thickness of 140 nm. The ArF resist solution used was prepared by compounding 5 parts by mass of a compound represented by the formula (R-0) given below, 1 part by mass of triphenylsulfonium nonafluoromethanesulfonate, 2 parts by mass of tributylamine, and 92 parts by mass of PGMEA. For the compound represented by the formula (R-0) given below, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula.

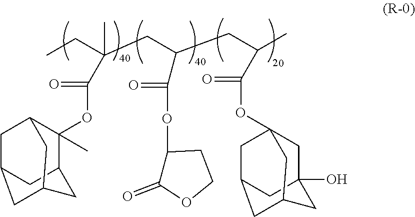

The numbers in the above formula (R-0) indicate the ratio of each constitutional unit.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern.

Defects of the obtained resist patterns of 55 nm L/S (1:1) and 80 nm L/S (1:1) were observed, and the results are shown in Table 2. In the table, “good” means that no major defects were found in the formed resist pattern, and “poor” means that major defects were found in the formed resist pattern.

### Comparative Example 2

The same operations as in Example 1B were carried out except that no underlayer film was formed so that a photoresist layer was formed directly on a SiO₂ substrate to obtain a positive type resist pattern. The results are shown in Table 2.

TABLE 2

| | Underlayer | | Acid | Resist |
|---|---|---|---|---|
| | film | | generating | pattern |
| | forming | Resolution | agent (parts | shape after |
| | material | (nmL/S) | by mass) | development |
| Example 1B | Example 1A | 55 | 10 | Good |
| Example 2B | Example 2A | 55 | 10 | Good |
| Example 3B | Example 3A | 55 | 10 | Good |
| Example 4B | Example 4A | 55 | 10 | Good |
| Example 5B | Example 5A | 55 | 10 | Good |
| Example 6B | Example 6A | 55 | 10 | Good |
| Example 7B | Example 7A | 55 | 10 | Good |
| Example 8B | Example 8A | 55 | 10 | Good |
| Example 9B | Example 9A | 55 | 10 | Good |
| Example 10B | Example 10A | 55 | 10 | Good |
| Example 11B | Example 11A | 55 | 10 | Good |
| Example 12B | Example 12A | 55 | 10 | Good |
| Example 13B | Example 13A | 55 | 10 | Good |
| Example 14B | Example 14A | 55 | 10 | Good |
| Example 15B | Example 15A | 55 | 10 | Good |
| Example 16B | Example 16A | 55 | 10 | Good |
| Example 17B | Example 17A | 55 | 10 | Good |
| Example 18B | Example 18A | 55 | 10 | Good |
| Example 21B | Example 21A | 55 | 10 | Good |
| Example 22B | Example 22A | 55 | 10 | Good |
| Example 23B | Example 23A | 55 | 10 | Good |
| Example 24B | Example 24A | 55 | 10 | Good |
| Example 25B | Example 25A | 55 | 10 | Good |
| Example 26B | Example 26A | 55 | 10 | Good |
| Example 27B | Example 27A | 55 | 10 | Good |
| Example 28B | Example 28A | 55 | 10 | Good |
| Example 29B | Example 29A | 55 | 10 | Good |
| Comparative | — | 80 | 26 | Poor |
| Example 2 | | | | |

As is evident from Table 1, Examples 1A to 18A and 21A to 29A using any of A-1 to A-12, which are the resins of the present embodiment, were favorable in terms of both solubility and etching resistance. On the other hand, Comparative Example 1 using CR-1 (phenol-modified dimethylnaphthaleneformaldehyde resin) resulted in poor etching resistance.

Further, as is evident from Table 2, Examples 1B to 18B and 21B to 29B using any of A-1 to A-12, which are the resins of the present embodiment, were confirmed to have a good resist pattern shape after development and have no major defects found. Further, each of Examples 1B to 18B and 21B to 29B was confirmed to be significantly superior to Comparative Example 2, in which no underlayer film was formed, in both resolution and sensitivity. Here, a good resist pattern shape after development indicates that the underlayer film forming materials for lithography used in Examples 1A to 18A and 21A to 29A have good adhesiveness to a resist material (photoresist material and the like).

### Examples 1C to 18C and 21C to 29C

A SiO₂ substrate with a film thickness of 300 nm was coated with the solution of the underlayer film forming materials for lithography of Examples 1A to 18A and 21A and 29A and baked at 240° C. for 60 seconds and further at 400° C. for 120 seconds to form each underlayer film with a film thickness of 80 nm. This underlayer film was coated with a silicon-containing intermediate layer material and baked at 200° C. for 60 seconds to form an intermediate layer film having a film thickness of 35 nm. This intermediate layer film was further coated with the above resist solution for ArF and baked at 130° C. for 60 seconds to form a photoresist layer having a film thickness of 150 nm. The silicon-containing intermediate layer material used was the silicon atom-containing polymer described in <Synthesis Example 1> of Japanese Patent Laid-Open No. 2007-226170. Then, the photoresist layer was mask exposed using an electron beam lithography system (manufactured by ELIONIX INC.; ELS-7500, 50 keV), baked (PEB) at 115° C. for 90 seconds, and developed for 60 seconds in 2.38% by mass tetramethylammonium hydroxide (TMAH) aqueous solution to obtain a 55 nm L/S (1:1) positive type resist pattern. Thereafter, the silicon-containing intermediate layer film (SOG) was dry etched with the obtained resist pattern as a mask using RIE-10NR manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Conditions for etching of resist intermediate layer film with resist pattern

Output: 50 W

Pressure: 20 Pa

Time: 1 min

Etching gas

Ar gas flow rate:CF₄ gas flow rate:O₂ gas flow rate=50:8:2 (sccm)

Conditions for etching of resist underlayer film with resist intermediate film pattern

Output: 50 W

Pressure: 20 Pa

Time: 2 min

Etching gas

Ar gas flow rate:CF₄ gas flow rate:O₂ gas flow rate=50:5:5 (sccm)

Conditions for etching of SiO₂ film with resist underlayer film pattern

Output: 50 W

Pressure: 20 Pa

Time: 2 min

Etching gas

Ar gas flow rate:C₅F₁₂ gas flow rate:C₂F₆ gas flow rate:O₂ gas flow rate
=50:4:3:1 (sccm)

### [Evaluation]

The pattern cross section (that is, the shape of the SiO₂ film after etching) obtained as described above was observed by using a product manufactured by Hitachi, Ltd., “electron microscope (S-4800)”. The observation results are shown in Table 3. In the table, “good” means that no major defects were found in the formed pattern cross section, and “poor” means that major defects were found in the formed pattern cross section.

TABLE 3

| | Underlayer film | Shape of | |
|---|---|---|---|
| | forming material | SiO2 film | Appearance |
| Example 1C | Example 1A | Rectangular | Good |
| Example 2C | Example 2A | Rectangular | Good |
| Example 3C | Example 3A | Rectangular | Good |
| Example 4C | Example 4A | Rectangular | Good |
| Example 5C | Example 5A | Rectangular | Good |
| Example 6C | Example 6A | Rectangular | Good |
| Example 7C | Example 7A | Rectangular | Good |
| Example 8C | Example 8A | Rectangular | Good |
| Example 9C | Example 9A | Rectangular | Good |
| Example 10C | Example 10A | Rectangular | Good |
| Example 11C | Example 11A | Rectangular | Good |
| Example 12C | Example 12A | Rectangular | Good |
| Example 13C | Example 13A | Rectangular | Good |
| Example 14C | Example 14A | Rectangular | Good |
| Example 15C | Example 15A | Rectangular | Good |
| Example 16C | Example 16A | Rectangular | Good |
| Example 17C | Example 17A | Rectangular | Good |
| Example 18C | Example 18A | Rectangular | Good |
| Example 21C | Example 21A | Rectangular | Good |
| Example 22C | Example 22A | Rectangular | Good |
| Example 23C | Example 23A | Rectangular | Good |
| Example 24C | Example 24A | Rectangular | Good |
| Example 25C | Example 25A | Rectangular | Good |
| Example 26C | Example 26A | Rectangular | Good |
| Example 27C | Example 27A | Rectangular | Good |
| Example 28C | Example 28A | Rectangular | Good |
| Example 29C | Example 29A | Rectangular | Good |

(Example 19) Purification of RBisF-1 with Acid

In a four necked flask (capacity: 1000 mL, with a detachable bottom), 150 g of a solution (10% by mass) formed by dissolving RBiF-1 obtained in Synthesis Example 4 in PGMEA was charged, and was heated to 80° C. with stirring. Then, 37.5 g of an aqueous oxalic acid solution (pH 1.3) was added thereto, and the resultant mixture was stirred for 5 minutes and then left to stand for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and removed by heating to 80° C. and reducing the pressure in the flask to 200 hPa or less. Thereafter, by diluting with PGMEA of EL grade (a reagent manufactured by Kanto Chemical Co., Inc.) such that the concentration of the PGMEA solution was adjusted to 10% by mass, a PGMEA solution of RBiF-1 with a reduced metal content was obtained.

(Example 20) Purification of BisP-1 with Acid

In the same manner as of Example 19 except that BisP-1 water was used instead of RBiF-1, and by adjusting the concentration to 10% by mass, a PGMEA solution of BisP-1 was obtained.

(Comparative Example 3) Purification of RBiF-1 with Ultrapure Water

In the same manner as of Example 19 except that ultrapure water was used instead of the aqueous oxalic acid solution, and by adjusting the concentration to 10% by mass, a PGMEA solution of RBiF-1 was obtained.

For the 10 mass % RBiF-1 solution in PGMEA before the treatment, the 10 mass % BisP-1 solution in PGMEA before the treatment, and the solutions obtained in Examples 19 and 20 and Comparative Example 3, the contents of various metals were measured by ICP-MS. The measurement results are shown in Table 4.

TABLE 4

| | Metal content (ppb) | | | | | |
|---|---|---|---|---|---|---|
| | Na | Mg | K | Fe | Cu | Zn |
| Before | >99 | 23.2 | >99 | >99 | 2.7 | 13.6 |
| treatment | | | | | | |
| RBiF-1 | | | | | | |
| Example 19 | 1.3 | 1.5 | 1.0 | 1.1 | 0.5 | 0.8 |
| Before | 55.6 | 1.1 | 2.3 | >99 | 10.0 | 11.5 |
| treatment | | | | | | |
| BisP-1 | | | | | | |
| Example 20 | <0.2 | <0.2 | <0.2 | 1.4 | 0.5 | 0.5 |
| Comparative | 2.5 | 2.6 | 1.6 | >99 | 2.4 | 3.1 |
| Example 3 | | | | | | |

### INDUSTRIAL APPLICABILITY

The resin of the present invention has high heat resistance, has high solvent solubility, and is applicable to a wet process. Therefore, a film forming material for lithography using the resin of the present invention, and a film for lithography thereof can be utilized widely and effectively in various applications that require such performances. Accordingly, the present invention can be utilized widely and effectively in, for example, electrical insulating materials, resins for resists, encapsulation resins for semiconductors, adhesives for printed circuit boards, electrical laminates mounted in electric equipment, electronic equipment, industrial equipment, and the like, matrix resins of prepregs mounted in electric equipment, electronic equipment, industrial equipment, and the like, buildup laminate materials, resins for fiber-reinforced plastics, resins for encapsulation of liquid crystal display panels, coating materials, various coating agents, adhesives, coating agents for semiconductors, resins for resists for semiconductors, resins for underlayer film formation, and the like. In particular, the present invention can be utilized particularly effectively in the field of films for lithography.

1. A resin comprising a constituent unit represented by the following formula (1) or (1)′: 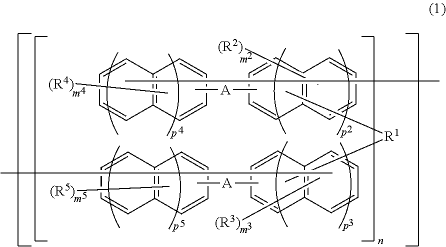
wherein
A is a single bond, an alkylene having 1 to 4 carbon atoms and optionally having a substituent, or a heteroatom;
R¹ is a 2n-valent group having 1 to 30 carbon atoms;
R² to R⁵ are each independently a linear alkyl group having 1 to 10 carbon atoms, a branched alkyl group having 3 to 10 carbon atoms, a cyclic alkyl group having 3 to 10 carbon atoms, an aryl group having 6 to 10 carbon atoms, an alkenyl group having 2 to 10 carbon atoms, a thiol group, or a hydroxyl group;
at least one R² and/or at least one R³ is a hydroxy group and/or a thiol group;
m² and m³ are each independently an integer of 0 to 8;
m⁴ and m⁵ are each independently an integer of 0 to 9;
n is an integer of 1 to 4; and
p² to p⁵ are each independently an integer of 0 to 2, and 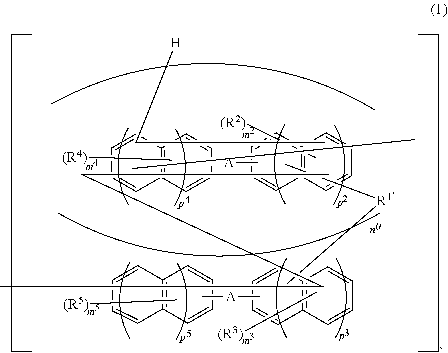
wherein
R^{1′} is a divalent group having 1 to 30 carbon atoms;
n⁰ is an integer of 1 to 10; and
A, R² to R⁵, m² to m⁵, and p² to p⁵ are as defined in the formula (1).

2. The resin according to claim 1, wherein the formula (1) is the following formula (2): 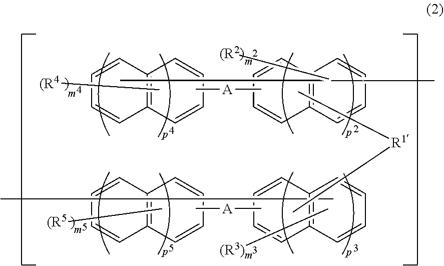
wherein
R^{1′} is a divalent group having 1 to 30 carbon atoms; and
A, R² to R⁵, m² to m⁵, and p² to p⁵ are as defined in the formula (1).

3. The resin according to claim 1, wherein p² to p⁵ are 0.

4. The resin according to claim 1, wherein A is a single bond.

5. The resin according to claim 1, wherein the formula (1) is the following formula (2a): 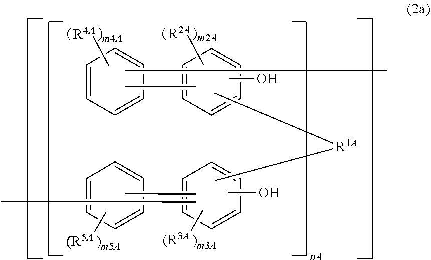
wherein
n^{A} and R^{1A} to R^{5A} are as defined in n and R¹ to R⁵ in the formula (1), respectively;
m^{2A} and m^{3A} are each independently an integer of 0 to 3; and
m^{4A} and m^{5A} are each independently an integer of 0 to 5.

6. The resin according to claim 1, wherein the formula (1) and the formula (1)′ are the following formula (2b) and the following formula (2b)′, respectively: 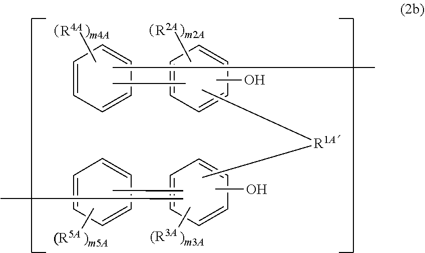
wherein
R^{1A′} is a divalent group having 1 to 30 carbon atoms;
R^{2A} to R^{5A} are as defined in R² to R⁵ in the formula (1), respectively;
m^{2A} and m^{3A} are each independently an integer of 0 to 3; and
m^{4A} and m^{5A} are each independently an integer of 0 to 5, and 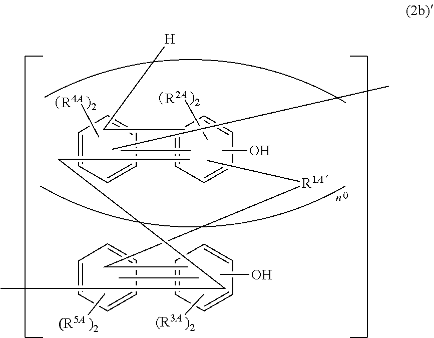
wherein
R^{1A′} is a divalent group having 1 to 30 carbon atoms;
R^{2A} to R^{5A} are as defined in R² to R⁵ in the formula (1), respectively;
m^{2A} and m^{3A} are each independently an integer of 0 to 3;
m^{4A} and m^{5A} are each independently an integer of 0 to 5; and
n⁰ is an integer of 1 to 10.

7. The resin according to claim 1, wherein the formula (1)′ is the following formula (3a)′ or the following formula (3b)′: 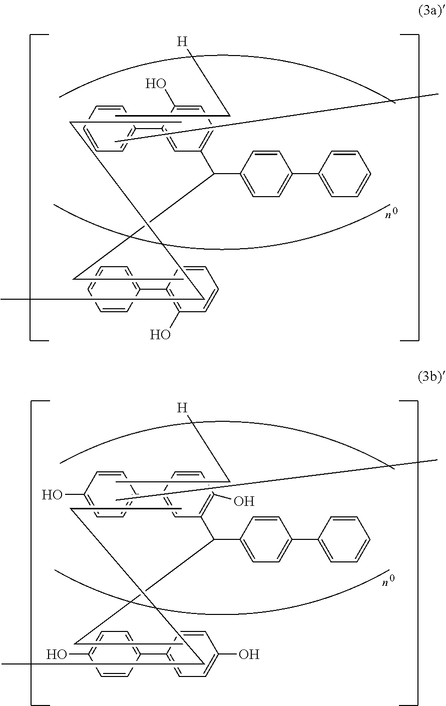
wherein n⁰ is an integer of 1 to 10.

8. The resin according to claim 1, wherein the resin comprises the constituent unit defined in claim 1, and one or two constituent units different from the constituent unit defined in claim 1.

9. The resin according to claim 1, further comprising a constituent unit represented by the following formula (U1) and/or a constituent unit represented by the following formula (U2): 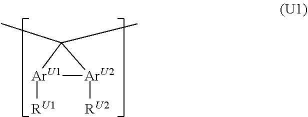
wherein
Ar^{U1} and Ar^{U2} are each independently a phenyl ring or a naphthalene ring; and
R^{U1} and R^{U2} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms, or an alkoxy group having 1 to 10 carbon atoms, and 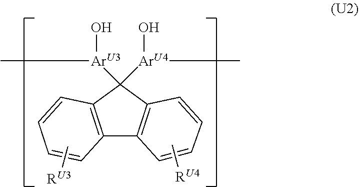
wherein
Ar^{U3} and Ar^{U4} are each independently a phenyl ring or a naphthalene ring; and
R^{U3} and R^{U4} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms or an alkoxy group having 1 to 10 carbon atoms.

10. The resin according to claim 1, wherein the resin comprises a block unit comprising the constituent unit represented by the formula (1) or the formula (1)′, where the block unit is represented by the following formula (4) or the following formula (4)′: 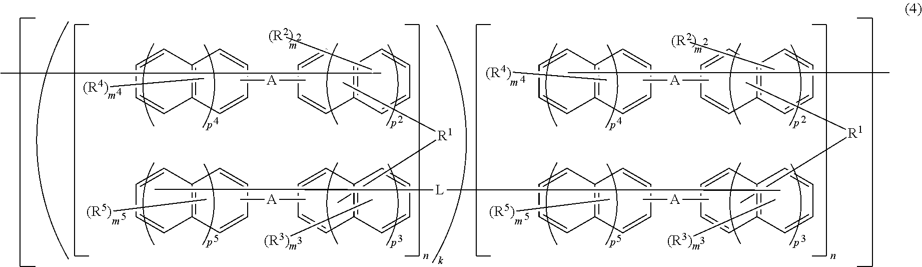
wherein
A, R¹ to R⁵, m² to m⁵, n, and p² to p⁵ are as defined in the formula (1);
L is a divalent group having 1 to 30 carbon atoms or a single bond; and
k is a positive integer, and 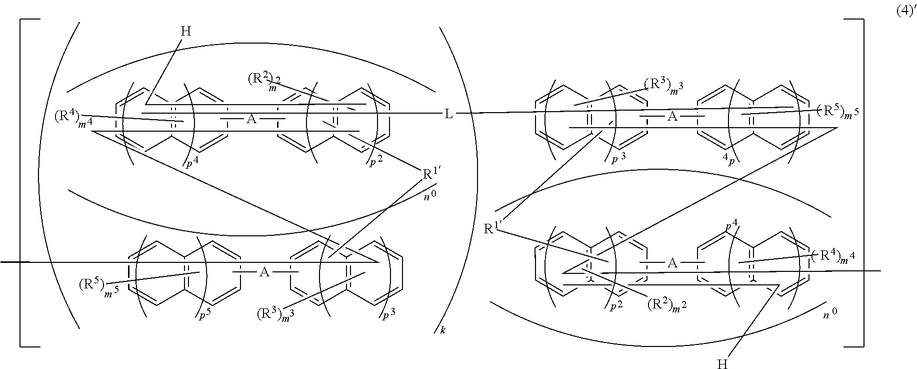
wherein
R^{1′} is a divalent group having 1 to 30 carbon atoms;
A, R² to R⁵, m² to m⁵, and p² to p⁵ are as defined in the formula (1);
L is a divalent group having 1 to 30 carbon atoms or a single bond;
k is a positive integer; and
n⁰ is an integer of 1 to 10.

11. The resin according to claim 10, wherein the formula (4) is the following formula (5): 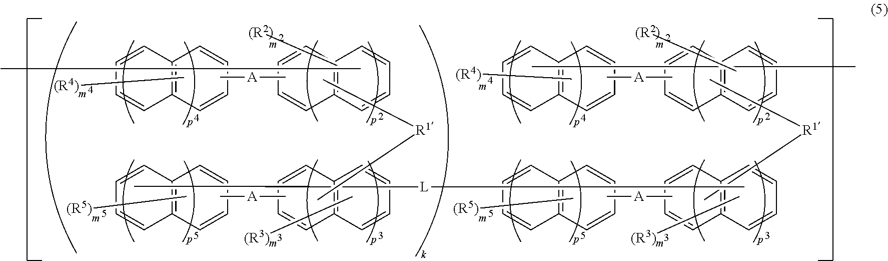
wherein
R^{1′} is a divalent group having 1 to 30 carbon atoms; and
A, R² to R⁵, m² to m⁵, p² to p⁵, L, and k are as defined in the formula (4).

12. The resin according to claim 10, wherein the formula (4) is the following formula (5a): 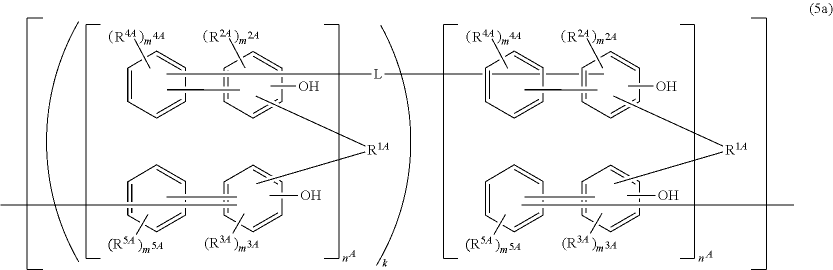
wherein,
n^{A}, R^{1A} to R^{5A}, L, and k are as defined in n, R¹ to R⁵, L, and k in the formula (4), respectively;
m^{2A} and m^{3A} are each independently an integer of 0 to 3; and
m^{4A} and m^{5A} are each independently an integer of 0 to 5.

13. The resin according to claim 10, wherein the formula (4) and the formula (4)′ are the following formula (5b) and the following formula (5b)′, respectively: 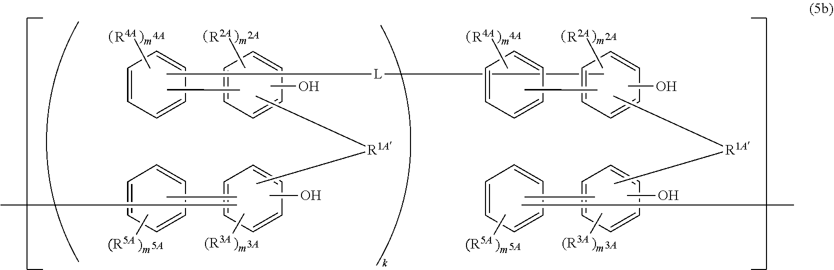
wherein
R^{1A′} is a divalent group having 1 to 30 carbon atoms;
R^{2A} to R^{5A}, L, and k are as defined in R² to R⁵, L, and k in the formula (4), respectively;
m^{2A} and m^{3A} are each independently an integer of 0 to 3; and
m^{4A} and m^{5A} are each independently an integer of 0 to 5. 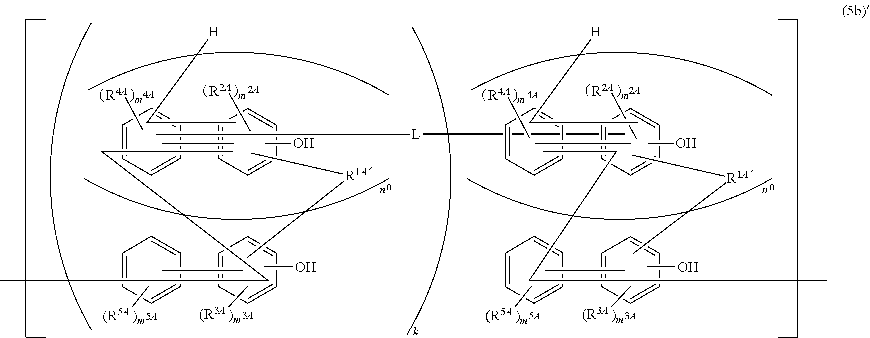
wherein
R^{1A′} is a divalent group having 1 to 30 carbon atoms;
R^{2A} to R^{5A}, L, and k are as defined in R² to R⁵, L, and k in the formula (4), respectively;
m^{2A} and m^{3A} are each independently an integer of 0 to 3;
m^{4A} and m^{5A} are each independently an integer of 0 to 5; and
n⁰ is an integer of 1 to 10.

14. The resin according to claim 10, wherein the resin comprises the block unit and one or two constituent units different from the constituent unit represented by the formula (1) or the formula (1)′.

15. The resin according to claim 10, further comprising a constituent unit represented by the following formula (U1) and/or a constituent unit represented by the following formula (U2): 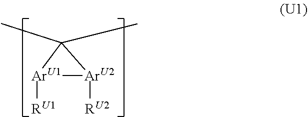
wherein
Ar^{U1} and Ar^{U2} are each independently a phenyl ring or a naphthalene ring; and
R^{U1} and R^{U2} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms, or an alkoxy group having 1 to 10 carbon atoms, and 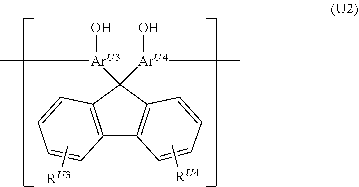
wherein
Ar^{U3} and Ar^{U4} are each independently a phenyl ring or a naphthalene ring; and
R^{U3} and R^{U4} are each independently a hydrogen atom, a linear alkyl group having 1 to 10 carbon atoms, a branched alkyl group having 3 to 10 carbon atoms, a cyclic alkyl group having 3 to 10 carbon atoms, an alkenyl group having 2 to 10 carbon atoms or an alkoxy group having 1 to 10 carbon atoms.

16. A composition comprising the resin according to claim 1.

17. The composition according to claim 16, further comprising a solvent.

18. The composition according to claim 16, further comprising an acid generating agent.

19. The composition according to claim 16, further comprising a crosslinking agent.

20. The composition according to claim 16, wherein the composition is used in film formation for lithography.

21. The composition according to claim 20, wherein the composition is used as a composition for resist film formation.

22. The composition according to claim 20, wherein the composition is used as a composition for underlayer film formation.

23. A resist pattern formation method, comprising:
a photoresist layer formation step of forming a photoresist layer on a substrate using the composition according to claim 21; and
a development step of irradiating a predetermined region of the photoresist layer formed through the photoresist layer formation step with radiation for development.

24. A resist pattern formation method, comprising:
an underlayer film formation step of forming an underlayer film on a substrate using the composition according to claim 22;
a photoresist layer formation step of forming at least one photoresist layer on the underlayer film formed through the underlayer film formation step; and
a step of irradiating a predetermined region of the photoresist layer formed through the photoresist layer formation step with radiation for development.

25. A circuit pattern formation method, comprising:
an underlayer film formation step of forming an underlayer film on a substrate using the composition according to claim 22;
an intermediate layer film formation step of forming an intermediate layer film on the underlayer film formed through the underlayer film formation step;
a photoresist layer formation step of forming at least one photoresist layer on the intermediate layer film formed through the intermediate layer film formation step;
a resist pattern formation step of irradiating a predetermined region of the photoresist layer formed through the photoresist layer formation step with radiation for development, thereby forming a resist pattern;
an intermediate layer film pattern formation step of etching the intermediate layer film with the resist pattern formed through the resist pattern formation step as a mask, thereby forming an intermediate layer film pattern;
an underlayer film pattern formation step of etching the underlayer film with the intermediate layer film pattern formed through the intermediate layer film pattern formation step as a mask, thereby forming an underlayer film pattern; and
a substrate pattern formation step of etching the substrate with the underlayer film pattern formed through the underlayer film pattern formation step as a mask, thereby forming a pattern on the substrate.

26. A method for purifying the resin according to claim 1, the method comprising:
an extraction step of bringing a solution containing the resin and an organic solvent that does not inadvertently mix with water into contact with an acidic aqueous solution, thereby carrying out extraction.
